(19) United States
(12) Patent Application Publication
(10) Pub. No.: US 2024/0414698 A1
(43) Pub. Date: Dec. 12, 2024

(54) METHOD AND APPARATUS FOR TBOMS TRANSMISSION

(71) Applicant: Telefonaktiebolaget LM Ericsson (publ), Stockholm (SE)

(72) Inventors: Ling SU, Beijing (CN); Zhipeng LIN, Nanjing, Jiangsu (CN); Robert Mark HARRISON, Grapevine, TX (US)

(73) Assignee: Telefonaktiebolaget LM Ericsson (publ), Stockholm (SE)

(21) Appl. No.: 18/580,738

(22) PCT Filed: Jul. 22, 2022
(86) PCT No.: PCT/CN2022/107365

§ 371 Date: Jan. 19, 2024

(30) Foreign Application Priority Data
Jul. 23, 2021 (WO) PCT/CN2021/108279

(51) Int. Cl. H04W 72/0446; H04L 1/00; H04L 1/1812; H04W 72/231

(52) U.S. Cl. CPC H04W 72/0446; H04L 1/0068; H04L 1/1812; H04W 72/231

(57) ABSTRACT

Various embodiments of the present disclosure provide a method for TBoMS transmission. The method which may be performed by a terminal device comprises encoding with low density parity check (LDPC) base graph on each code block (CB) of a Transport Block over Multiple Slots (TboMS), wherein the TBoMS comprises multiple slots; and performing rate matching on the LDPC code for each of the multiple slots of the TBoMS, wherein a time unit of the rate matching is per slot in the TBoMS, and wherein the TBoMS comprises one or more CBs.

### FIELD OF THE INVENTION

The present disclosure generally relates to communication networks, and more specifically, to method and apparatus for Transport Block over Multiple Slots (TBoMS) transmission.

### BACKGROUND

This section introduces aspects that may facilitate a better understanding of the disclosure. Accordingly, the statements of this section are to be read in this light and are not to be understood as admissions about what is in the prior art or what is not in the prior art.

Communication service providers and network operators have been continually facing challenges to deliver value and convenience to consumers by, for example, providing compelling network services and performance. With the rapid development of networking and communication technologies, wireless communication networks such as long-term evolution (LTE) and new radio (NR) networks are expected to enhance coverage. For example, in order to enhance coverage, TBoMS transmission may be performed.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

Various embodiments of the present disclosure mainly aim at providing methods, apparatus and computer programs for TBoMS transmission. Other features and advantages of embodiments of the present disclosure will also be understood from the following description of specific embodiments when read in conjunction with the accompanying drawings, which illustrate, by way of example, the principles of embodiments of the present disclosure.

According to a first aspect of the present disclosure, there is provided a method performed by a terminal device. The method comprises: encoding with low density parity check, LDPC, base graph on each code block, CB, of a Transport Block over Multiple Slots, TBoMS, wherein the TBoMS comprises multiple slots; and performing rate matching on the LDPC code for each of the multiple slots of the TBoMS, wherein a time unit of the rate matching is per slot in the TBoMS, and wherein the TBoMS comprises one or more CBs.

In accordance with some exemplary embodiments, a rate matching output sequence length Eᵣ for an r-th CB may be determined by:

$${E}_{r} = {N}_{L} \cdot {Q}_{m} \cdot ⌊ \frac{G}{{N}_{L} \cdot {Q}_{m} \cdot {C}^{′} \cdot M} ⌋ ,$$

if j≤C′−mod(G/(N_{L}·Qₘ),C′)−1; otherwise

$${E}_{r} = {N}_{L} \cdot {Q}_{m} \cdot ⌈ \frac{G}{{N}_{L} \cdot {Q}_{m} \cdot {C}^{′} \cdot M} ⌉ ;$$

where N_{L} is a number of transmission layers that the transport block is mapped onto; Qₘ is a modulation order; G is a total number of coded bits available for transmitting the transport block; C′=C if CBGTI is not present in the DCI scheduling the transport block, C is a number of CBs for a TBoMS transmission, otherwise C′ is a number of scheduled CBs of the transport block; and M is a number of times that a CB is rate matched.

In accordance with some exemplary embodiments, the method may further comprise receiving a first indication indicating a first number of slots for a TBoMS transmission; and determining a set of slots to be used for the TBoMS transmission based on the first indication and obtained TDD or FDD configuration information.

In accordance with some exemplary embodiments, the TBoMS may comprise one CB.

In accordance with some exemplary embodiments, one or more of the followings applies:
a same redundancy version, RV, is indicated or pre-determined for all CBs;
a respective RV is indicated or pre-determined for each CB;
a same RV pattern is indicated or pre-determined for all CBs, wherein an RV cycle according to the RV pattern is performed within a CB, or across CBs;
a respective RV pattern is indicated or pre-determined for each CB;
a same starting RV is indicated or pre-determined for all CBs according to the RV pattern; or
a respective starting RV is indicated or pre-determined for each CB according to the RV pattern.

In accordance with some exemplary embodiments, the method further comprises: performing one or more of the followings, in response to a Physical Uplink Control Channel, PUCCH, of Hybrid Automatic Repeat Request, HARQ-acknowledge, ACK, overlaps with a slot of the TBoMS transmission:
puncturing the HARQ-ACK into the TBoMS transmission in the overlapping slot;
puncturing the HARQ-ACK into the TBoMS transmission in the overlapping slot in response to a number of HARQ-ACK bits being lower than a pre-determined or configured threshold;
puncturing the HARQ-ACK into the TBoMS transmission in the overlapping slot in response to no uplink shared channel, UL-SCH, in the overlapping slot; or
puncturing the HARQ-ACK into the TBoMS transmission in the overlapping slot according to a decreasing order of PHY priority indexes in response to the number of HARQ-ACK bits exceeding a maximum number of HARQ bits to be punctured into a Physical Uplink Shared Channel, PUSCH, in one slot.

According to a second aspect of the present disclosure, there is provided an apparatus which may be implemented as a terminal device. The apparatus comprises one or more processors and one or more memories comprising computer program codes. The one or more memories and the computer program codes are configured to, with the one or more processors, cause the apparatus at least to perform any step of the method according to the first aspect of the present disclosure.

According to a third aspect of the present disclosure, there is provided a computer-readable medium having computer program codes embodied thereon which, when executed on a computer, cause the computer to perform any step of the method according to the first aspect of the present disclosure.

According to a fourth aspect of the present disclosure, there is provided an apparatus which may be implemented as a terminal device. The apparatus comprises: an encoding unit configured to encode with low density parity check, LDPC, base graph on each code block, CB, of a Transport Block over Multiple Slots, TBoMS, wherein the TBoMS comprises multiple slots; and a performing unit configured to perform rate matching on the LDPC code for each of the multiple slots of the TBoMS, wherein a time unit of the rate matching is per slot in the TBoMS, and wherein the TBoMS comprises one or more CBs.

According to a fifth aspect of the present disclosure, there is provided a method performed by a network node. The method comprises receiving a Transport Block over Multiple Slots, TBoMS, wherein the TBoMS comprises multiple slots and comprises one or more code blocks, CBs, wherein each CB of the TBoMS was encoded with low density parity check, LDPC, base graph, and the LDPC code was rate-matched for each of the multiple slots of the TBoMS.

In accordance with some exemplary embodiments, the method may further comprise transmitting a first indication indicating a first number of slots for a TBoMS transmission.

According to a sixth aspect of the present disclosure, there is provided an apparatus which may be implemented as a network node. The apparatus comprises one or more processors and one or more memories comprising computer program codes. The one or more memories and the computer program codes are configured to, with the one or more processors, cause the apparatus at least to perform any step of the method according to the fifth aspect of the present disclosure.

According to a seventh aspect of the present disclosure, there is provided a computer-readable medium having computer program codes embodied thereon which, when executed on a computer, cause the computer to perform any step of the method according to the fifth aspect of the present disclosure.

According to an eighth aspect of the present disclosure, there is provided an apparatus which may be implemented as a network node. The apparatus comprises a receiving unit configured to receive a Transport Block over Multiple Slots, TBoMS, wherein the TBoMS comprises multiple slots and comprises one or more code blocks, CBs, wherein each CB of the TBoMS was encoded with low density parity check, LDPC, base graph, and the LDPC code was rate-matched for each of the multiple slots of the TBoMS.

### BRIEF DESCRIPTION OF THE DRAWINGS

The disclosure itself, the preferable mode of use and further objectives are best understood by reference to the following detailed description of the embodiments when read in conjunction with the accompanying drawings, in which:

FIG. 1 is a flowchart illustrating a method according to some embodiments of the present disclosure;

FIG. 2a illustrates an example of TBoMS with multiple RVs, with different time units for rate matching.

FIG. 2b illustrates an example of TBoMS with single RV, with different time units for rate matching.

FIG. 2c illustrates an example of TOT determination.

FIG. 2d illustrates another example of TOT determination.

FIG. 3 illustrates an example of rate matching.

FIG. 4a illustrates an example of code block segmentation.

FIG. 4b illustrates another example of code block segmentation.

FIG. 5 is a flowchart illustrating another method according to some embodiments of the present disclosure;

FIG. 6A is a block diagram illustrating an apparatus according to some embodiments of the present disclosure;

FIG. 6B is a block diagram showing a terminal device according to an embodiment of the disclosure;

FIG. 6C is a block diagram showing a base station according to an embodiment of the disclosure;

FIG. 7 is a block diagram illustrating a telecommunication network connected via an intermediate network to a host computer in accordance with some embodiments of the present disclosure;

FIG. 8 is a block diagram illustrating a host computer communicating via a base station with a UE over a partially wireless connection in accordance with some embodiments of the present disclosure;

FIG. 9 is a flowchart illustrating a method implemented in a communication system, in accordance with an embodiment of the present disclosure;

FIG. 10 is a flowchart illustrating a method implemented in a communication system, in accordance with an embodiment of the present disclosure;

FIG. 11 is a flowchart illustrating a method implemented in a communication system, in accordance with an embodiment of the present disclosure; and

FIG. 12 is a flowchart illustrating a method implemented in a communication system, in accordance with an embodiment of the present disclosure.

### DETAILED DESCRIPTION

The embodiments of the present disclosure are described in detail with reference to the accompanying drawings. It should be understood that these embodiments are discussed only for the purpose of enabling those skilled persons in the art to better understand and thus implement the present disclosure, rather than suggesting any limitations on the scope of the present disclosure. Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Furthermore, the described features, advantages, and characteristics of the disclosure may be combined in any suitable manner in one or more embodiments. One skilled in the relevant art will recognize that the disclosure may be practiced without one or more of the specific features or advantages of a particular embodiment. In other instances, additional features and advantages may be recognized in certain embodiments that may not be present in all embodiments of the disclosure.

As used herein, the term “communication network” refers to a network following any suitable communication standards, such as new radio (NR), long term evolution (LTE), LTE-Advanced, wideband code division multiple access (WCDMA), high-speed packet access (HSPA), and so on. Furthermore, the communications between a terminal device and a network node in the communication network may be performed according to any suitable generation communication protocols, including, but not limited to, the first generation (1G), the second generation (2G), 2.5G, 2.75G, the third generation (3G), 4G, 4.5G, 5G communication protocols, and/or any other protocols either currently known or to be developed in the future.

The term “network node” refers to a network device in a communication network via which a terminal device accesses to the network and receives services therefrom. The network node may refer to a base station (BS), an access point (AP), a multi-cell/multicast coordination entity (MCE), a controller or any other suitable device in a wireless communication network. The BS may be, for example, a node B (NodeB or NB), an evolved NodeB (eNodeB or eNB), a next generation NodeB (gNodeB or gNB), a remote radio unit (RRU), a radio header (RH), a remote radio head (RRH), a relay, a low power node such as a femto, a pico, and so forth.

Yet further examples of the network node comprise multi-standard radio (MSR) radio equipment such as MSR BSs, network controllers such as radio network controllers (RNCs) or base station controllers (BSCs), base transceiver stations (BTSs), transmission points, transmission nodes, positioning nodes and/or the like. More generally, however, the network node may represent any suitable device (or group of devices) capable, configured, arranged, and/or operable to enable and/or provide a terminal device access to a wireless communication network or to provide some service to a terminal device that has accessed to the wireless communication network.

The term “terminal device” refers to any end device that can access a communication network and receive services therefrom. By way of example and not limitation, the terminal device may refer to a mobile terminal, a user equipment (UE), or other suitable devices. The UE may be, for example, a subscriber station, a portable subscriber station, a mobile station (MS) or an access terminal (AT). The terminal device may include, but not limited to, portable computers, image capture terminal devices such as digital cameras, gaming terminal devices, music storage and playback appliances, a mobile phone, a cellular phone, a smart phone, a tablet, a wearable device, a personal digital assistant (PDA), a vehicle, and the like.

As yet another specific example, in an Internet of things (IoT) scenario, a terminal device may also be called an IoT device and represent a machine or other device that performs monitoring, sensing and/or measurements etc., and transmits the results of such monitoring, sensing and/or measurements etc. to another terminal device and/or a network equipment. The terminal device may in this case be a machine-to-machine (M2M) device, which may in a 3rd generation partnership project (3GPP) context be referred to as a machine-type communication (MTC) device.

As one particular example, the terminal device may be a UE implementing the 3GPP narrow band Internet of things (NB-IoT) standard. Particular examples of such machines or devices are sensors, metering devices such as power meters, industrial machinery, or home or personal appliances, e.g. refrigerators, televisions, personal wearables such as watches etc. In other scenarios, a terminal device may represent a vehicle or other equipment, for example, a medical instrument that is capable of monitoring, sensing and/or reporting etc. on its operational status or other functions associated with its operation.

As used herein, the terms “first”, “second” and so forth refer to different elements. The singular forms “a” and “an” are intended to include the plural forms as well, unless the context clearly indicates otherwise. The terms “comprises”, “comprising”, “has”, “having”, “includes” and/or “including” as used herein, specify the presence of stated features, elements, and/or components and the like, but do not preclude the presence or addition of one or more other features, elements, components and/or combinations thereof. The term “based on” is to be read as “based at least in part on”. The term “one embodiment” and “an embodiment” are to be read as “at least one embodiment”. The term “another embodiment” is to be read as “at least one other embodiment”. Other definitions, explicit and implicit, may be included below.

Wireless communication networks are widely deployed to provide various telecommunication services such as voice, video, data, messaging and broadcasts. As described previously, in order to enhance coverage, a terminal device such as a UE may need to perform TBoMS transmission.

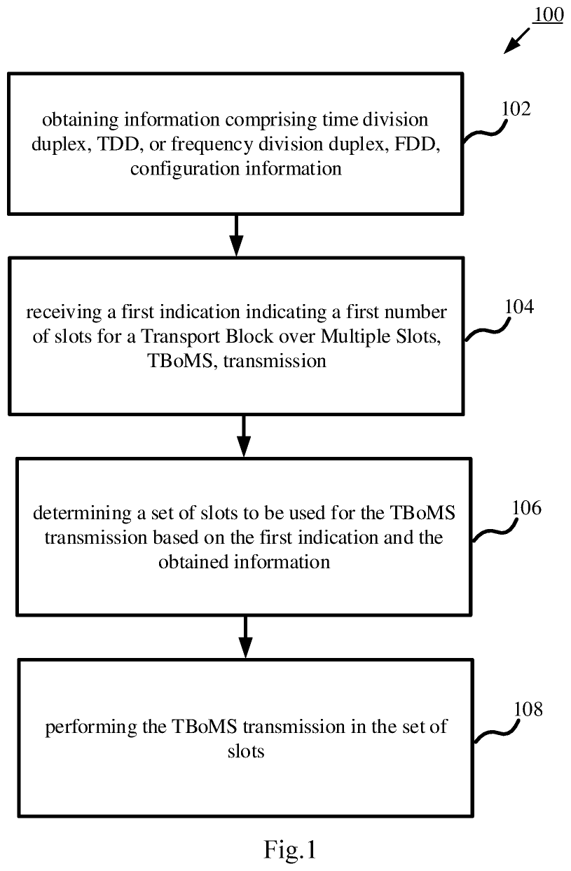

FIG. 1 is a flowchart illustrating a method according to some embodiments of the present disclosure. The method 100 illustrated in FIG. 1 may be performed by a terminal device or an apparatus communicatively coupled to the terminal device. In accordance with an exemplary embodiment, the terminal device such as a UE may be configurable to connect to a network node such as a gNB, for example, by performing TBoMS transmission.

According to the exemplary method 100 illustrated in FIG. 1, the terminal device may obtain information at block 102. The information may comprise time division duplex, TDD, or frequency division duplex, FDD, configuration information.

In accordance with some exemplary embodiments, the obtained information may further comprise: at least one of: a Transmission Occasion for TBoMS, TOT, size, a number of TOTs in the TBoMS transmission, and a number of repetitions of a TOT. The TOT size may be referred to as TOT length, and may indicate the number of slots per TOT. If the number of slots per TOT is indicated, it means each TOT for the TBoMS has the same size.

The structure of TBoMS will be according to only one of these two options (to be down-selected in RAN1 #106-e)
Option 3, if a design based on single RV is adopted.
Option 4, if a design based on different RVs (multiple RVs) is adopted.

The following three options for rate-matching for TBoMS are considered for down-selection during RAN1 #106-e, where only one option will be selected:
Option a: Rate-matching is performed per slot;
Option b: Rate matching is performed continuously across all the allocated slot(s) per TOT;
Option c: Rate matching is performed continuously across all the allocated slots/TOTs for TBoMS

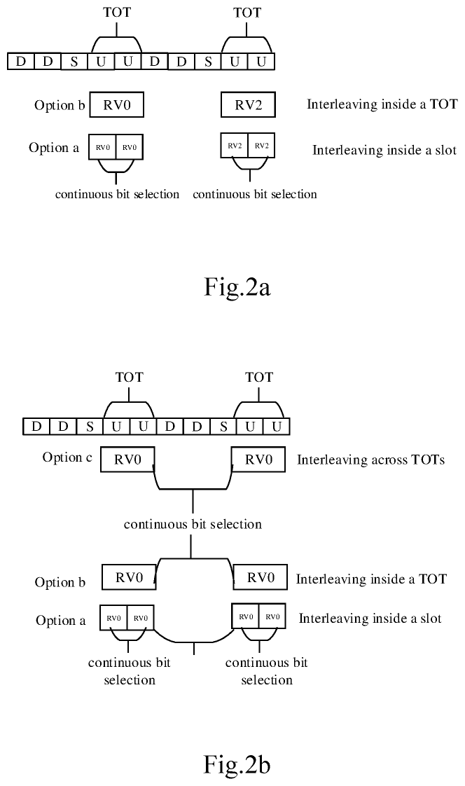

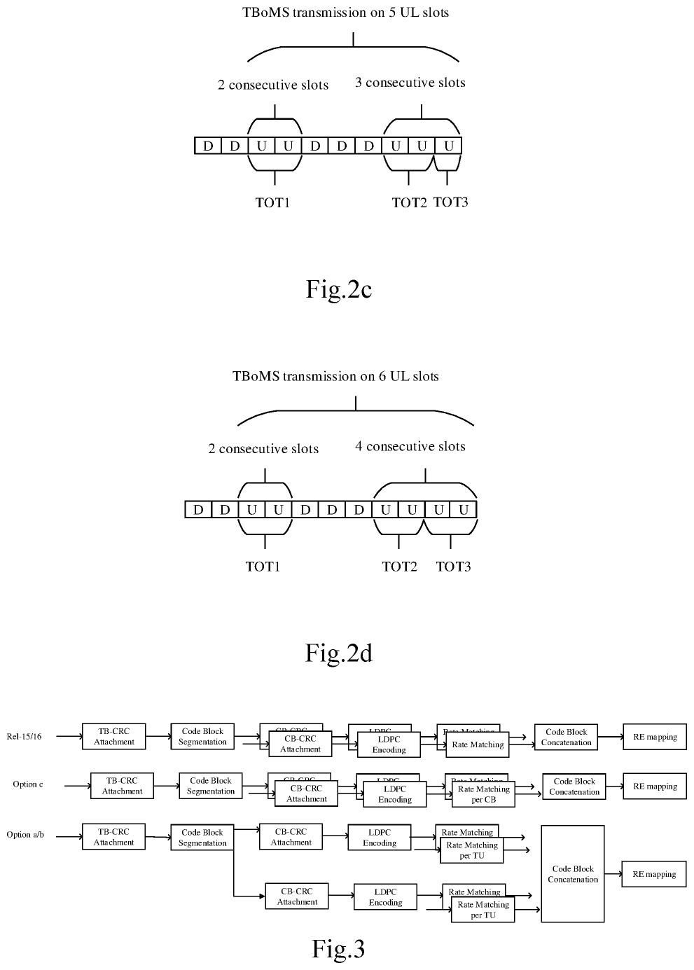

For TBoMS, the agreements on single or multiple RVs per TBoMS and time unit of rate matching can lead to several combinations. For Option 4, TBoMS with multiple RVs, the possible time units for rate matching are Option a (per slot), and Option b (per TOT). RVs update at the border of slot or TOT. Option a defines time unit of bit selection and bit interleaving as a slot but doesn't restrict how bits are selected across slots. For example, Option a doesn't preclude that UE does continuous bit selection from circular buffer for the UL slots in a TOT. Therefore, TOT Option 4-a (the combination of Option 4 and Option a) and 4-b can have the same encoded bits selected, and the difference lies in whether interleaving is done intra-slot or intra-TOT. The transmission of TBoMS is equivalent to repetitions of TOT. The number of TOTs in a TBoMS equals the number of repetitions of TOT in a TBoMS. An example of option 4-a and 4-b for a TBoMS over four slots in TDD UL/DL configuration of DDSUU is illustrated in FIG. 2a.

The combinations of Option 3 (TBoMS with single RV) and Option a/b/c can have the continuous bits selected across all slots of the TBoMS, but interleaved with different time units, as illustrated in FIG. 2b.

In accordance with some exemplary embodiments, the terminal device may obtain the information by receiving a second indication indicating at least one of the TOT size, the number of TOTs, and a number of repetitions of a TOT. In an example, the second indication may be received in a time domain resource assignment, TDRA, table, a separate downlink control information, DCI, field, or a separate radio resource control, RRC, information element, IE.

When scheduling the transmission of TBoMS, it was agreed in RAN1 #105e that “Number of slots allocated for TBoMS is determined by using a row index of a TDRA list, configured via RRC”. As mentioned above, for TBoMS of multiple RVs, a UE may need to determine the size of a TOT (such as a number of slots in a TOT) for TBS determination. For a TBoMS containing a single RV, if the time unit of rate-matching is a TOT, the UE also needs to know the size of a TOT. For example, in UL-heavy TDD configuration or FDD configuration, the consecutive slots for UL transmission can be divided into multiple smaller TOTs for the ease of interleaving. Therefore, for TBoMS based on single or multiple RVs, UE needs to determine the size of a TOT and the number of TOTs in a TBoMS.

In accordance with some exemplary embodiments, the terminal device may determine the TOT size based on a number of consecutive slots for the TBoMS transmission. In this case, different sizes of TOTs may be determined depending on the actual number of consecutive UL slots in each time instance. It may be desirable that the UL slots to be used to carry the TBoMS do not vary once the UE has begun transmitting a TBoMS. If the UL slots were to vary, the available resource to transmit the TBoMS varies, and the code rate that the TBoMS is transmitted with will not match what it was scheduled for, thereby degrading performance or losing spectral efficiency. Therefore, in some embodiments, avoiding varying UL slots of a TBoMS is accomplished by determining the UL slots that can potentially carry a TBoMS as the UL slots indicated by semi-static signaling such as tdd-UL-DL-ConfigurationCommon or tdd-UL-DL-ConfigurationDedicated. This semi-static signaling ensures that the UL slots are fixed, since it takes effect before or after a PUSCH transmission, unlike DCI signaling that could happened during the transmission of a TBoMS.

In accordance with some exemplary embodiments, the terminal device may determine the TOT size based on a number of consecutive available slots for the TBoMS transmission.

In accordance with some exemplary embodiments, the terminal device may determine the TOT size and the number of TOTs based on a minimum number of consecutive slots for the TBoMS transmission.

In these embodiments, assuming in the TBoMS transmission, the minimum number of consecutive UL slots is N1, and for the transmission instance with larger number, say N2 (N2>N1), of consecutive UL slots, it can be split into multiple, say ceil(N2/N1), TOTs and the first ceil(N2/N1)−1 TOTs have a size of N1 slots, the last TOT in this transmission occasion has N2−N1*(ceil(N2/N1)−1) slots.

FIG. 2c gives an illustration of an example with N1=2 and N2=3 in a case when 2 transmission instances with 2 consecutive UL slots in the first time instance and 3 consecutive UL slots in the 2nd time instance are used for the TBoMS transmission. And 3 TOTs are determined, the first 2 TOTs have size of 2 UL slots while the last TOT has size of 1 UL slot.

In this way, the size and number of TOTs are simply determined by the minimum number of consecutive UL slots in one TBoMS transmission.

In accordance with some exemplary embodiments, the terminal device may determine the TOT size and the number of TOTs based on the greatest common divisor of a plurality of sets of consecutive slots for the TBoMS transmission.

In these embodiments, different TOT will have same size. FIG. 2d gives an illustration of an example when the TBoMS transmission has 2 transmission instances with the first transmission instance having 2 consecutive UL slots and the 2nd transmission instance having 4 consecutive UL slots, then the TOT size is equal to 2 which is the greatest common divisor of 2 and 4. So the first transmission occasion and the second transmission occasion will have 1 and 2 TOTs respectively with same TOT size of 2 UL slots.

For TBoMS with different RVs, the number of TOTs per TBoMS equals the number of repetitions of a TOT per TBoMS. The number of slots per TOT*the number of TOTs in a TBoMS=number of slots for a TBoMS.

In accordance with some exemplary embodiments, the terminal device may receive a third indication indicating whether the TOT size of each TOT in the TBoMS transmission is same or different.

UE can be explicitly or implicitly indicated or it can be predetermined whether the TOTs used for transmission of a TBoMS have the same or different numbers of slots.

For TBoMS with multiple RVs, all TOTs have the same size. For TBoMS with a single RV, a UE can assume TOTs of different sizes are available for the transmission of a TBoMS. For example, in the TDD configuration of DDDSUDDSUU, the UE transmits in the first TOT, which is a single UL slot, and then in the second TOT, which consists of two UL consecutive slots. Different TOT sizes in a TBoMS will cause higher UE complexity than the same TOT size for a TBoMS. If the number of slots per TOT is indicated, it means each TOT for the TBoMS has the same size.

In accordance with some exemplary embodiments, the TBoMS transmission is in available slots or at least one available TOT in which all the slots in accordance with its TOT size are the available slots. For example, if a UE is indicated the TOT size of two slots, in DDDSUDDSUU, the first TOT has only one UL slot and is not considered as an available TOT.

In accordance with some exemplary embodiments, the available slot may be determined by one or more of the followings:
cell specific time division duplex, TDD, uplink downlink configuration;
   As an example, tdd-UL-DL-ConfigurationCommon is used to determine which slot is available for the transmission of TBoMS.
Dedicated UE-specific TDD uplink downlink configuration;
   As an example, tdd-UL-DL-ConfigurationDedicated is used to determine which slot is available for the transmission of TBoMS.
a configuration in downlink control information, DCI, or higher layer signaling for the TBoMS transmission; or
   e.g. which one or both TDD uplink downlink signalings (i.e. dedicated signaling, tdd-UL-DL-ConfigurationDedicated or common signaling) are to be used for available slot determination can be based on DCI or higher layer signaling scheduling TBoMS
   if such configuration in DCI is absent, cell specific and dedicated UE-specific TDD uplink downlink configuration are used if provided.
   Higher layer signaling can be used to schedule TBoMS with configured grant.
a Synchronization Signal Block, SSB, configuration.

In accordance with some exemplary embodiments, the available slot is determined as one or more of the following: an uplink, UL, slot; a flexible slot, in which all the allocated symbols for the TBoMS transmission are UL symbols; a flexible slot, in which all the allocated symbols for the TBoMS transmission are UL or flexible symbols; a special slot, in which all the allocated symbols for the TBoMS transmission are UL symbols; or a special slot, in which all the allocated symbols for the TBoMS transmission are UL or flexible symbols.

In accordance with some exemplary embodiments, if a UE is indicated to transmit TBoMS based on available TOTs, it determines a number of available TOTs with one or more of below methods, where K is a nominal number of slots indicated for a TBoMS.

If the TOTs in a TBoMS have different sizes, the total number of slots in the determined TOTs for the TBoMS is equal to K. If TOT size is indicated as N slots, the number of determined TOTs per

$$TBoMS = ⌈ \frac{K}{N} ⌉ or ⌊ \frac{K}{N} ⌋ ,$$

and the total number of slots in the TBoMS is adjusted from K to

$$N \cdot ⌈ \frac{K}{N} ⌉ or N \cdot ⌊ \frac{K}{N} ⌋$$

In accordance with some exemplary embodiments, determining the set of slots to be used for the TBoMS transmission based on the first indication and the configuration information comprises: determining a number of available TOTs based on whether the TOT size of each TOT in the TBoMS transmission is same or different; and determining a second number of slots in the set of slots to be used for the TBoMS transmission based on the number of available TOTs.

In accordance with some exemplary embodiments, the method 100 of FIG. 1 further comprises: setting the second number of slots to be equal to the first number of slots when a TOT size of a TOT in the TBoMS is different from another TOT size of a TOT in the TBoMS.

Turning back to FIG. 1, the terminal device may receive a first indication indicating a first number of slots for a Transport Block over Multiple Slots, TBoMS, transmission at block 104. The first number of slots may be represented by K in the context. The first number of slots may be given by a row of a TDRA table that can be indicated by a DCI message.

At block 106, the terminal device may determine a set of slots to be used for the TBoMS transmission based on the first indication and the obtained information. In accordance with some exemplary embodiments, a second number of slots in the set of slots may be determined based on at least one of the TOT size, the number of TOTs, and a number of repetitions of a TOT. The location information about the set of slots may be determined based on the TDD or FDD configuration information.

At block 108, the terminal device may perform the TBoMS transmission in the set of slots.

For the TBoMS transmission, the following issues may be considered, such as code block segmentation, collision handling, and UCI multiplexing.

### Code Block Segmentation

In accordance with some exemplary embodiments, the transport blocks, TBs, for the TBoMS transmission are segmented into one or more code blocks, CBs.

In Rel-15 and Rel-16, CB segmentation happens when 1) N_{info}>3824 and R≤1/4, or 2) the quantized intermediate number of information bits N_{info}′=8424 and R>¼. CB segmentation is necessary because LDPC's Base Graph 1 (BG1) and Base Graph 2 (BG2) can process a maximum of 8448 and 3824 information bits respectively. The upper limit of the two LDPC base graphs still holds for TBoMS, and therefore CB segmentation is needed for TBoMS in order to reuse LDPC coding.

In Rel-15 and Rel-16, if the TBS and code rate meet the prerequisites of CB segmentation, multiple CBs are generated, each with the same number of information bits per code block. Each CB undergoes separate LDPC coding and rate matching before being concatenated, and then RE mapping in a slot. (Scrambling, modulation etc., before RE mapping are not mentioned here for simplicity.) For a TBoMS, each CB is processed independently with LDPC coding and rate matching. Rate matching with CB segmentation is illustrated in FIG. 3.

In NR Rel-15 and Rel-16, one rate matching is performed per CB. If no CB segmentation happens, one rate matching is performed per TB. For Option c, each CB has one rate matching. Each CB's rate matching output sequence length can be determined by the legacy method, then concatenated and continuously mapped to REs in multiple slots. But now with option a and option b for a TBoMS, a CB may undergo multiple times of rate matching depending on the time unit of rate matching. The legacy method of determination of rate matching output sequence length is for a CB and it can't be used directly for multiple times of rate matching for a CB.

In accordance with some exemplary embodiments, each TOT in the TBoMS transmission has N slots, the first number of slots is K, the number of TOTs is

$$⌈ \frac{K}{N} ⌉ or ⌊ \frac{K}{N} ⌋ ,$$

and a second number of slots in the set of slots is

$$N \cdot ⌈ \frac{K}{N} ⌉ or N \cdot ⌊ \frac{K}{N} ⌋ .$$

In accordance with some exemplary embodiments, the second number of slots is determined by one or more of the followings:
Option 1,

$$A = N \cdot C \cdot ⌈ \frac{K}{N \cdot C} ⌉$$

Option 1a,

$$A = N \cdot C \cdot max ( 1 , ⌊ \frac{K}{N \cdot C} ⌋ )$$

Option 1b,

$$A = N \cdot C \cdot max ( 1 , ⌊ \frac{K}{N \cdot C} ⌋ ) ,$$

if mod(K,C)<C/2; otherwise

$$A = N \cdot C \cdot ⌈ \frac{K}{N \cdot C} ⌉$$

Option 2, A=K
where A denotes the second number of slots, K denotes the first number of slots; C denotes a number of code blocks, CBs, for the TBoMS transmission, C=1 if no CB segmentation happens; if rate matching is performed per slot, N=1, and if rate matching is performed per TOT, N equals the TOT size.

If the rate matched code block does not fit into an integer number of rate matching time units, it is possible to adjust the number of rate matching time units, while keeping the time unit sizes equal. In this way, the total number of slots in a TBoMS may be different from the nominal number of slots in the TBoMS, K, but the rate matched code block will fit into an integer number of rate matching time units. Note that this method exploits the Rel-15/16 property of TBS determination that the TBS is the same for each coded block. Because the TBS is the same, then a single scaling factor can be used that applies to all code blocks that adjusts the number of rate matching time units. The above Options 1, 1a, and 1b capture this approach.

It is also possible to adjust the size of the rate matching time units such that they are unequally sized in order to fit a rate matched code block into its portion of the resource elements of a TBoMS. One time unit could be rate matched over a portion of a slot or a TOT, while the remaining time units could be rate matched with a second size that is a full slot or TOT. This allows the rate matched code blocks to fit in the number of nominal number of slots allocated for the TBoMS, and corresponds to the above Option 2.

With Options 1, 1a, and 1b, each rate matching is over the same size time unit (that is, over the same number of OFDM symbols) and it may use more slots than configured. Option 2 means the number of slots for the actual TBoMS transmission is the same as its configuration, and the rate matching may not be over the same number of symbols. If K is not divided by C and N, some enhancement is needed.

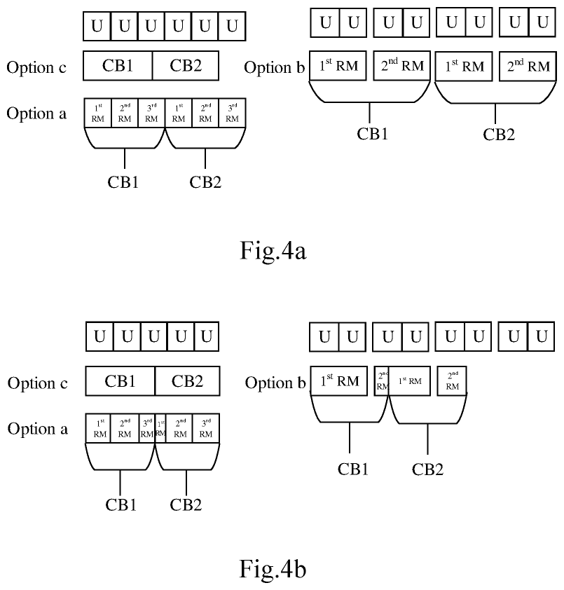

For example, a TBoMS over five slots is segmented into two CBs. Option 1 is illustrated in FIG. 4a. With option a, when the time unit of rate matching is a slot, each CB is rate matched three times. With option b, when the time unit of rate matching is a two slot long TOT, each CB is rate matched two times. In this example, option a and option b, respectively, use 6 and 8 slots for actual transmission.

In accordance with some exemplary embodiments, a TOT size is less than or equal to

$$⌊ \frac{K}{C} ⌋ ,$$

where K denotes the first number of slots, C denotes a number of code blocks, CBs, for the TBoMS transmission.

In accordance with some exemplary embodiments, each CB uses a same number of REs and does not include an integer number of time units for rate matching, and the time unit is a slot or a TOT. For a first CB as beginning CB of the TBoMS transmission, an output sequence length of the last rate matching of the first CB is determined by the REs between a beginning of the time unit including a CB boundary and the CB boundary. For a last CB as ending CB of the TBoMS transmission, the output sequence length of the first rate matching of the last CB is determined by the REs between the CB boundary and the end of the time unit including the CB boundary. For a CB other than the first CB and the last CB, the output sequence length of the first rate matching of the CB is determined by the REs between the CB boundary and an end of the time unit including the CB boundary, and the output sequence length of the last rate matching is determined by the REs between the beginning of the time unit including the CB boundary and the CB boundary. The CB boundary is between the transmission of any two adjacent CBs.

As illustrated in FIG. 4b, TBoMS over five slots with two CBs has the CB boundary in the middle of the third slot. For Option a, the last rate matching of CB1 selects coded bits for the first half of the third slot, and the first rate matching of CB2 selects coded bits for the remaining portion of the slot. For option b, a TOT consists of two slots. The first rate matching of CB2 selects coded bits for the latter one and a half slots in the second TOT.

In accordance with some exemplary embodiments, one or more of the followings applies:
Alt 1: a same redundancy version, RV, is indicated or pre-determined for all CBs;
Alt 2: a respective RV is indicated or pre-determined for each CB;
Alt 3: a same RV pattern is indicated or pre-determined for all CBs, wherein an RV cycle according to the RV pattern is performed within a CB, or across CBs;
RVs cycle according to the RV pattern either within a CB, or across CBs;
Alt 4: a respective RV pattern is indicated or pre-determined for each CB;
Alt 5: a same starting RV is indicated or pre-determined for all CBs according to the RV pattern; or
Alt 6: a respective starting RV is indicated or pre-determined for each CB according to the RV pattern.

For example, for option 3, Alt 1 and Alt 2 support all CBs use the same or different RVs respectively. For option 4, RV patterns for different CBs can be the same or different according to Alt 3 and Alt 4.

With Alt 3, one possibility is that multiple RVs cycle across the multiple times of rate matching for a CB. Another one is that multiple RVs cycle across the multiple times of rate matching of all CBs, namely if one RV pattern is configured for the TBoMS, and the starting RV for the first CB is indicated, the starting RV of a subsequent CB follows the last RV of the previous CB according to the RV pattern.

### Collision Handling

In accordance with some exemplary embodiments, the method 100 of FIG. 1 further comprises: performing one of the followings, in response to the TBoMS transmission in a slot being decided to be dropped:
dropping the transmission of the TOT starting from the slot to be dropped;
dropping the transmission of the TOT which contains the slot to be dropped;
dropping the transmission of the TBoMS starting from the TOT which contains the slot to be dropped.

Different from PUSCH repetition, slots of the TBoMS comprising single RV are not repetition of each other. So dropping transmission in one slot is more harmful for TBoMS than PUSCH repetition. In RV0, systematic bits are taken out from the circular buffer ahead of parity bits, and the former is more important for UE decoding. Therefore, if the time unit of interleaving is small, e.g. per slot or TOT, the transmission of TBoMS in the first slot(s) or TOT(s) have more systematic bits than the latter slot or TOT.

In accordance with some exemplary embodiments, the method 100 of FIG. 1 further comprises: ignoring, in response to one or more collisions happened in the first X slots of the TBoMS transmission, the one or more collisions.

In accordance with some exemplary embodiments, the method 100 of FIG. 1 further comprises: ignoring, in response to one or more collisions happened in the first X TOTs of the TBoMS transmission, the one or more collisions.

In accordance with some exemplary embodiments, X is configured by RRC or DCI message, or is predetermined, or equals a minimum number of slots which have sufficient resource elements, REs, to transmit all or a part of systematic bits. In an example, X may be predetermined as one.

### UCI Multiplexing

In Rel-15 and Rel-16, if PUCCH and PUSCH overlap in a slot, the UCI may be multiplexed in PUSCH in the slot. Rel-17 TBoMS has the transmission of a TB over multiple slots. It needs consideration how to deal with PUCCH overlapping with a TBoMS. In this Disclosure, we discuss how multiplexing UCI on PUSCH is done, e.g. by rate matching or puncturing.

In Rel-15/16, UCI multiplexing on PUSCH is done per slot, by puncturing or rate-matching around PUSCH. ACK/NACK>2 bit and other UCI are rate matched, 1-2 bit ACK/NACK punctured. Due to code-block-group-based HARQ feedback, ACK/NACK size can be very large in NR. Puncturing large ACK/NACK into PUSCH leads to severe PUSCH performance degradation. Therefore, reserved resources for puncturing PUSCH are based on 2 ACK/NACK bits.

Rate matching requires the UE to calculate the number of modulated UCI symbols first, map UCI on the agreed RE resources in a slot, and then rate match PUSCH in the remaining resources in the slot. The rate-matching includes bit selection and bit interleaving. The number of selected bits is based on the number of remaining REs in the slot for PUSCH. For TBoMS, the possible time units of rate-matching under discussion are a slot, a TOT, and all slots of a TBoMS. If the time unit of rate-matching is a TOT or all slots of the TBoMS, multiplexing UCI by rate-matching it in any slot of the time unit has an impact on PUSCH transmission in other slots of the time unit. For an example of time unit of rate-matching being two slots, if UCI is to be multiplexed in the second slot, a UE needs to calculate the available REs in the two slots for PUSCH excluding those for UCI and then select PUSCH bits and interleave. The complexity of rate-matching increases for TBoMS with a time unit of rate matching larger than a slot. However puncturing UCI into TBoMS doesn't increase complexity regardless of time unit of rate-matching.

As discussed above, it can be advantageous to carry a single redundancy version, such as RV0, across multiple slots of a TBoMS. Such a mapping can allow a lower code rate and improve performance over where multiple RVs are used. However, because TBoMS occupies multiple slots, when a single slot of an RV is lost, because there is no mechanism defined to retransmit a specific portion of an RV that is lost, all slots of the TBoMS may need to be retransmitted. This means that TBoMS transmissions may need to be more conservatively scheduled than, for example, PUSCH repetition type A, in order to avoid the efficiency loss from losing all TBoMS slots, whereas PUSCH repetition type A could retransmit an RV contained in a slot. Therefore, some embodiments, puncture in a limited number of bits, rather than multiplexing a large number of bits into a TBoMS. In some such embodiments, because CSI often has a relatively large payload, CSI is dropped rather than multiplexing the CSI onto a slot of a PUSCH containing TBoMS.

One example of two-bit HARQ-ACK is for the two codewords of DL MIMO of 5-8 layers. In reality, the transmission of HARQ-ACK of more than two bits in a slot is possible, for example, in carrier aggregation, or for multiple sub-slot HARQ in a slot.

In accordance with some exemplary embodiments, the method 100 of FIG. 1 further comprises: performing one or more of the followings, in response to a Physical Uplink Control Channel, PUCCH, of Hybrid Automatic Repeat Request, HARQ-acknowledge, ACK, overlaps with a slot of the TBoMS transmission:
puncturing the HARQ-ACK into the TBoMS transmission in the overlapping slot;
puncturing the HARQ-ACK into the TBoMS transmission in the overlapping slot in response to a number of HARQ-ACK bits being lower than a pre-determined or configured threshold;
puncturing the HARQ-ACK into the TBoMS transmission in the overlapping slot in response to no uplink shared channel, UL-SCH, in the overlapping slot; or
puncturing the HARQ-ACK into the TBoMS transmission in the overlapping slot according to a decreasing order of PHY priority indexes in response to the number of HARQ-ACK bits exceeding a maximum number of HARQ bits to be punctured into a Physical Uplink Shared Channel, PUSCH, in one slot.

In accordance with some exemplary embodiments, the number of HARQ-ACK bits allowed to be transmitted in a slot of the TBoMS transmission by puncturing is configured by RRC or DCI message, or is pre-determined.

In accordance with some exemplary embodiments, reserved resources for HARQ ACK/NACK having over-2-bit are configured by RRC or DCI message or are pre-determined.

In accordance with some exemplary embodiments, if a PUCCH carrying Channel State Information, CSI, is scheduled to be transmitted in a same slot as the TBoMS transmission, the CSI is not multiplexed in to the PUSCH carrying TBoMS in the slot, and the CSI is not transmitted, i.e. ‘dropped’.

In accordance with some exemplary embodiments, an Uplink Control Information, UCI, overlapping with the TBoMS transmission is multiplexed on the TBoMS transmission in one or more of the followings: the first slot of the first TOT; the first slot of the TOT overlapping with the scheduled UCI transmission slot; the slot overlapping with the scheduled UCI transmission slot.

In accordance with some exemplary embodiments, the UCI comprises at least one of HARQ-ACK, or CSI.

In accordance with some exemplary embodiments, a rate matching output sequence length Eᵣ for an r-th CB is determined by:

$${E}_{r} = {N}_{L} \cdot {Q}_{m} \cdot ⌊ \frac{G}{{N}_{L} \cdot {Q}_{m} \cdot {C}^{′} \cdot M} ⌋ ,$$

if j≤C′−mod(G/(N_{L}·Qₘ),C′)−1; otherwise

$${E}_{r} = {N}_{L} \cdot {Q}_{m} \cdot ⌈ \frac{G}{{N}_{L} \cdot {Q}_{m} \cdot {C}^{′} \cdot M} ⌉ ;$$

where N_{L} is a number of transmission layers that the transport block is mapped onto; Qₘ is a modulation order; G is a total number of coded bits available for transmitting the transport block; C′=C if CBGTI is not present in the DCI scheduling the transport block, C is a number of CBs for the TBoMS transmission, otherwise C′ is a number of scheduled CBs of the transport block; and M is a number of times a CB is rate matched.

In accordance with some exemplary embodiments, the M is determined by one of the followings:

$$M = ⌈ \frac{K}{N \cdot C} ⌉ ; or M = max ( 1 , ⌊ \frac{K}{N \cdot C} ⌋ ) ,$$

where K denotes the first number of slots, C denotes a number of CBs for the TBoMS transmission, and if rate matching is performed per slot, N=1, if rate matching is performed per TOT, N equals the TOT size.

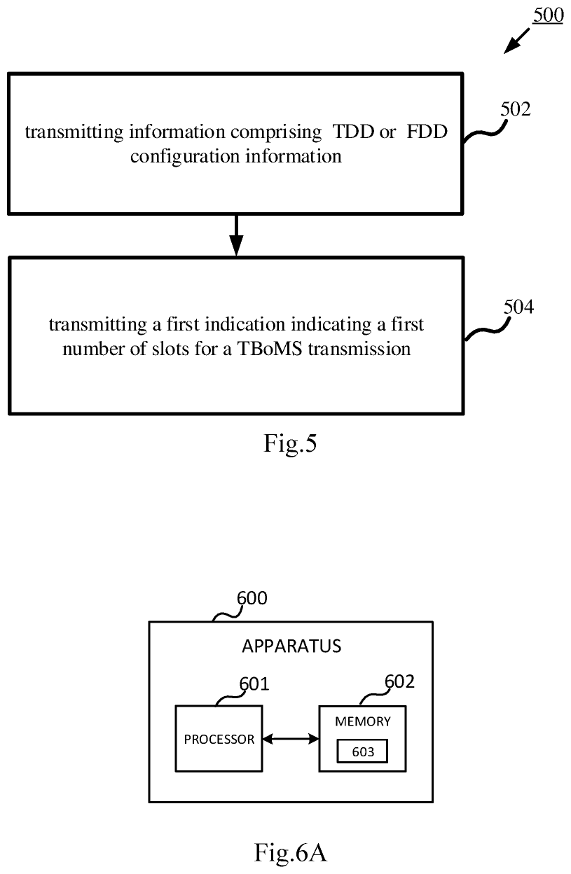

FIG. 5 is a flowchart illustrating another method according to some embodiments of the present disclosure. The method 500 illustrated in FIG. 5 may be performed by a network node or an apparatus communicatively coupled to the terminal device. In accordance with an exemplary embodiment, the network node such as a gNB may be configurable to connect to a terminal device such as a UE, for example, by performing TBoMS transmission.

According to the exemplary method 500 illustrated in FIG. 5, the network node may transmit information which comprising time division duplex, TDD, or frequency division duplex, FDD, configuration information at block 502.

At block 504, the network node may transmit a first indication indicating a first number of slots for a Transport Block over Multiple Slots, TBoMS, transmission.

In accordance with some exemplary embodiments, in the method 500 of FIG. 5, transmitting the information comprises transmitting the information in a time domain resource assignment, TDRA, table, a separate downlink control information, DCI, field, or a separate radio resource control, RRC, information element, IE.

In accordance with some exemplary embodiments, the method 500 of FIG. 5 further comprises: transmitting a third indication indicating whether the TOT size of each TOT in the TBoMS transmission is same or different.

In accordance with some exemplary embodiments, the method 500 of FIG. 5 further comprises: indicating available slots or at least one available TOT in which all the slots in accordance with its TOT size are the available slots.

In accordance with some exemplary embodiments, the method 500 of FIG. 5 further comprises: avoid any other transmission in the first X slots of the TBoMS transmission.

In accordance with some exemplary embodiments, the method 500 of FIG. 5 further comprises: avoid any other transmission in the first X TOTs of the TBoMS transmission.

This disclosure provides solutions to support TBoMS transmission which facilitates coverage enhancement.

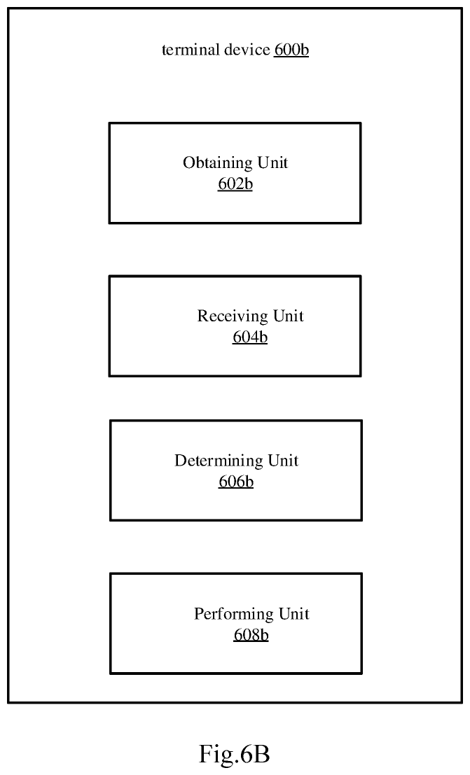

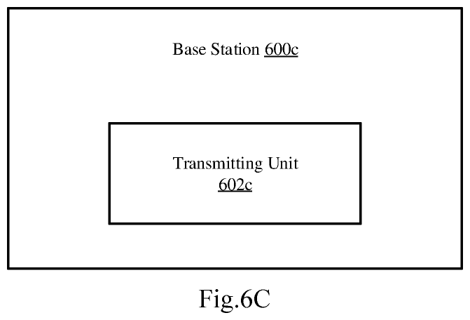

FIG. 6A is a block diagram illustrating an apparatus 600 according to various embodiments of the present disclosure. As shown in FIG. 6A, the apparatus 600 may comprise one or more processors such as processor 601 and one or more memories such as memory 602 storing computer program codes 603. The memory 602 may be non-transitory machine/processor/computer readable storage medium. In accordance with some exemplary embodiments, the apparatus 600 may be implemented as an integrated circuit chip or module that can be plugged or installed into a terminal device as described with respect to FIG. 1, or a network node as described with respect to FIG. 5. In such case, the apparatus 600 may be implemented as a terminal device as described with respect to FIG. 1, or a network node as described with respect to FIG. 5.

In some implementations, the one or more memories 602 and the computer program codes 603 may be configured to, with the one or more processors 601, cause the apparatus 600 at least to perform any operation of the method as described in connection with FIG. 1. In other implementations, the one or more memories 602 and the computer program codes 603 may be configured to, with the one or more processors 601, cause the apparatus 600 at least to perform any operation of the method as described in connection with FIG. 5. Alternatively or additionally, the one or more memories 602 and the computer program codes 603 may be configured to, with the one or more processors 601, cause the apparatus 600 at least to perform more or less operations to implement the proposed methods according to the exemplary embodiments of the present disclosure.

Various embodiments of the present disclosure provide an apparatus for TBoMS transmission. In an exemplary embodiment, the apparatus may be implemented in a terminal device such as a UE. FIG. 6B illustrates a block diagram showing a terminal device according to an embodiment of the disclosure. As shown in FIG. 6B, the terminal device 600b comprises an obtaining unit 602b, a receiving unit 604b, a determining unit 606b and a performing unit 608b. The obtaining unit 602b may be operable to carry out the operation in block 102, the receiving unit 604b may be operable to carry out the operation in block 104, determining unit 602b may be operable to carry out the operation in block 106, and the performing unit 604b may be operable to carry out the operation in block 108. Optionally, the obtaining unit 602b, a receiving unit 604b, the determining unit 606b and/or the performing unit 608b may be operable to carry out more or less operations to implement the proposed methods according to the exemplary embodiments of the present disclosure.

Various embodiments of the present disclosure provide an apparatus for TBoMS transmission. In an exemplary embodiment, the apparatus may be implemented in a network node such as a base station. FIG. 6C illustrates a block diagram showing a base station according to an embodiment of the disclosure. As shown in FIG. 6C, the base station 600c comprises a transmitting unit 602c. The transmitting unit 602c may be operable to carry out the operations in blocks 402 and 404. Optionally, the transmitting unit 602c may be operable to carry out more or less operations to implement the proposed methods according to the exemplary embodiments of the present disclosure.

Hereinafter may be some further details of the embodiments of the present disclosure.

### Code Block Segmentation

In Rel-15 and Rel-16, Code Block (CB) segmentation applies if TBS>3824 and BG2 ais used.

In 38.214 v16.4.0 section 5.3.1.2, when N_{info}>3824, TBS is determined as follows.
quantized intermediate number of information bits

$${N}_{info}^{′} = max ( 3840 , {2}^{n} \times round ( \frac{{N}_{info} - 24}{{2}^{n}} ) ) ,$$

where n=└log₂(N_{info}−24)┘−5 and ties in the round function are broken towards the next largest integer.

```
- if R≤1/4
$TBS = 8 \cdot C \cdot ⌈ \frac{{N}_{inf o}^{′} + 24}{8 \cdot C} ⌉ - 24 , where C = ⌈ \frac{{N}_{inf o}^{′} + 24}{3816} ⌉$
    else
    if N_{info}′ > 8424
      $TBS = 8 \cdot C \cdot ⌈ \frac{{N}_{inf o}^{′} + 24}{8 \cdot C} ⌉ - 24 , where C = ⌈ \frac{{N}_{inf o}^{′} + 24}{8424} ⌉$
  else
      $TBS = 8 \cdot ⌈ \frac{{N}_{inf o}^{′} + 24}{8} ⌉ - 24$
  end if
end if
```

Kᵣ=K is the number of bits for the code block number r.

The bit sequence Cᵣₖ is calculated as:

```
s = 0 ;
for r = 0 to C −1
  for k = 0 to K′−L−1
    cᵣₖ = bₛ ;
    s = s + 1 ;
  end for
  if C > 1
```

The sequence cᵣ₀,cᵣ₁,cᵣ₂,cᵣ₃, . . . , c_{r(K′-L-1)} is used to calculate the CRC parity bits pᵣ₀,rᵣ₁, pᵣ₂, . . . , p_{r(L-1)} according to Clause 5.1 with the generator polynomial g_{CRC24B} (D)

```
    for k = K′−L to K′−1
        cᵣₖ = P_{r(k+L-K′)};
    end for
  end if
  for k = K′ to K −1 -- Insertion of filler bits
      cᵣₖ =< NULL > ;
  end for
end for
```

LDPC and rate matching for each CB is illustrated in FIG. 3.

### Bit Selection

Bit selection and bit interleaving are two steps of rate matching.

In 38.212 v16.6.0

### 5.4.2 Rate Matching for LDPC Code

The rate matching for LDPC code is defined per coded block and consists of bit selection and bit interleaving. The input bit sequence to rate matching is d₀,d₁,d₂, . . . , d_{N-1}, The output bit sequence after rate matching is denoted as f₀,f₁,f₂, . . . , f_{E-1},

### 5.4.2.1 Bit Selection

Denoting by Eᵣ the rate matching output sequence length for the r-th coded block, where the value of Eᵣ is determined as follows:
Set j=0
for r=0 to C−1
if the r-th coded block is not scheduled for transmission as indicated by CBGTI according to Clause 5.1.7.2 for DL-SCH and 6.1.5.2 for UL-SCH in [6, TS 38.214]

```
  Eᵣ = 0;
  else
    if j ≤ C'−mod(G/(N_{L} ·Qₘ),C')−1
      ${E}_{r} = {N}_{L} \cdot {Q}_{m} \cdot ⌊ \frac{G}{{N}_{L} \cdot {Q}_{m} \cdot {C}^{′}} ⌋ ;$
    else
      ${E}_{r} = {N}_{L} \cdot {Q}_{m} \cdot ⌈ \frac{G}{{N}_{L} \cdot {Q}_{m} \cdot {C}^{′}} ⌉ ;$
  end if
j = j+1;
end if
end for
```

where
   N_{L} is the number of transmission layers that the transport block is mapped onto;
   Qₘ is the modulation order;
   G is the total number of coded bits available for transmission of the transport block;
   C′=C if CBGTI is not present in the DCI scheduling the transport block and C′ is the number of scheduled code blocks of the transport block if CBGTI is present in the DCI scheduling the transport block.

Denote by rv_{id}, the redundancy version number for this transmission (rv_{id}=0, 1, 2 or 3), the rate matching output bit sequence eₖ, k=0,1,2, . . . , E−1, is generated as follows, where k₀ is given by Table 5.4.2.1-2 according to the value of rv_{id} and LDPC base graph:

```
k = 0 ;
j = 0 ;
while k < E
if d₍ₖ_{₀} _{+ j)mod N}_{_{cb}} ≠<NULL>
  eₖ = d₍ₖ_{₀} _{+ j)mod N}_{_{cb}} ;
  k = k + 1 ;
end if
j = j + 1 ;
end while
```

### UCI on PUSCH

In 38.212 v16.6.0

### 6.3.2.4 Rate Matching

### 6.3.2.4.1 UCI Encoded by Polar Code

### 6.3.2.4.1.1 HARQ-ACK

For HARQ-ACK transmission on PUSCH with UL-SCH, the number of coded modulation symbols per layer for HARQ-ACK transmission, denoted as Q_{ACK}′, is determined as follows:

$${Q}_{ACK}^{′} = min \{ ⌈ \frac{( {O}_{ACK} + {L}_{ACK} ) \cdot {β}_{offset}^{PUSCH} \cdot {\sum }_{l = 0}^{{N}_{symb , all}^{PUSCH} - 1} {M}_{s c}^{UCI} ( l )}{{\sum }_{r = 0}^{{C}_{UL - SCH} - 1} {K}_{r}} ⌉ , ⌈ α \cdot {\sum }_{l = {l}_{0}}^{{N}_{symb , all}^{PUSCH} - 1} {M}_{s c}^{UCI} ( l ) ⌉ \}$$

where
   O_{ACK} is the number of HARQ-ACK bits;
   if O_{ACK}≤360 L_{ACK}=11; otherwise L_{ACK} is the number of CRC bits for HARQ-ACK determined according to Clause 6.3.1.2.1;
   β_{offset}^{PUSCH}=β_{offset}^{HARQ-ACK};
   C_{UL-SCH} is the number of code blocks for UL-SCH of the PUSCH transmission;
   if the DCI format scheduling the PUSCH transmission includes a CBGTI field indicating that the UE shall not transmit the r-th code block, Kdr=0; otherwise, Kᵣ is the r-th code block size for UL-SCH of the PUSCH transmission;
   M_{sc}^{PUSCH} is the scheduled bandwidth of the PUSCH transmission, expressed as a number of subcarriers;
   M_{sc}^{PT-RS} (l) is the number of subcarriers in OFDM symbol l that carries PTRS, in the PUSCH transmission;
   M_{sc}^{UCI} (l) is the number of resource elements that can be used for transmission of UCI in OFDM symbol l, for l=0,1,2, . . . , N_{symb,all}^{PUSCH}−1, in the PUSCH transmission and N_{symb,all}^{PUSCH} is the total number of OFDM symbols of the PUSCH, including all OFDM symbols used for DMRS;
   for any OFDM symbol that carries DMRS of the PUSCH, M_{sc}^{UCI}(l)=0;
   for any OFDM symbol that does not carry DMRS of the PUSCH, M_{sc}^{UCI} (l)=M_{sc}^{PUSCH}−M_{sc}^{PT-RS}(l);
   α is configured by higher layer parameter scaling;
   l₀ is the symbol index of the first OFDM symbol that does not carry DMRS of the PUSCH, after the first DMRS symbol(s), in the PUSCH transmission.

For HARQ-ACK transmission on PUSCH without UL-SCH, the number of coded modulation symbols per layer for HARQ-ACK transmission, denoted as Q_{ACK}′, is determined as follows

$${Q}_{ACK}^{′} = min \{ ⌈ \frac{( {O}_{ACK} + {L}_{ACK} ) \cdot {β}_{offset}^{PUSCH}}{R \cdot {Q}_{m}} ⌉ , ⌈ α \cdot {\sum }_{l = {l}_{0}}^{{N}_{symb , all}^{PUSCH} - 1} {M}_{s c}^{UCI} ( l ) ⌉ \}$$

where
   O_{ACK} is the number of HARQ-ACK bits;
   if O_{ACK}≥360 L_{ACK}=1; otherwise L_{ACK} is the number of CRC bits for HARQ-ACK defined according to Clause 6.3.1.2.1;
   β_{offset}^{PUSCH}=β_{offset}^{HARQ-ACK};
   M_{sc}^{PUSCH} is the scheduled bandwidth of the PUSCH transmission, expressed as a number of subcarriers;
   M_{sc}^{PTRS} (l) is the number of subcarriers in OFDM symbol l that carries PTRS, in the PUSCH transmission;
   M_{sc}^{UCI} (l) is the number of resource elements that can be used for transmission of UCI in OFDM symbol l, for l=0,1,2, . . . , N_{symb,all}^{PUSHC}−1, in the PUSCH transmission and N_{symb,all}^{PUSCH} is the total number of OFDM symbols of the PUSCH, including all OFDM symbols used for DMRS;
   for any OFDM symbol that carries DMRS of the PUSCH, M_{sc}^{UCI}(l)=0;
   for any OFDM symbol that does not carry DMRS of the PUSCH, M_{sc}^{UCI} (l)=M_{sc}^{PUSCH}−M_{sc}^{PT-RS}(l);
   l₀ is the symbol index of the first OFDM symbol that does not carry DMRS of the PUSCH, after the first DMRS symbol(s), in the PUSCH transmission;
   R is the code rate of the PUSCH, determined according to Clause 6.1.4.1 of [6, TS38.214];
   Qₘ is the modulation order of the PUSCH;
a is configured by higher layer parameter scaling.

### PHY Priority Index

Rel-16 supports a two-level PHY priority index indication of:
Scheduling Request (SR): SR configuration may have a PHY priority index indication as an RRC field in SR resource configuration.

Note: PHY priority index is only used to let PHY know the priority. MAC will perform prioritization based on LCH priorities.
HARQ-ACK: PHY priority index may be indicated in DL DCI (Format 1_1 and 12) for dynamic assignments by the field “Priority indicator”. while for SPS the PHY priority index is implicit from the PHY priority index of the HARQ-ACK codebook configured for SPS. may be indicated by RRC configuration.
PUSCH: For DG (Dynamic Grant) PHY priority index, may be indicated in UL DCI (Format 0_1 and 0_2) and for CG the PHY priority index may be indicated by CG configuration.
A-periodic and semi-persistent CSI on PUSCH: PHY priority index may be indicated in UL DCI (Format 0_1 and 0_2).

PHY priority index 0 is defined as low priority and PHY priority index 1 is defined as high priority. In Rel-16, UCI (Uplink Control Information) is multiplexed in a PUCCH or a PUSCH only if PHY priority index of UCI and the PHY priority index of PUCCH or PUSCH is the same. Different priority multiplexing is expected to be supported in Rel-17.

PUSCH repetition based on available slot in Rel-17

In Rel-15 slot aggregation, also known as PUSCH repetition Type A has been supported, where number of slot-based PUSCH repetitions is semi-statically configured. In Rel-16, the number of PUSCH repetitions can be dynamically configured with DCI.

In Rel-15/16, PUSCH repetition Type A allows a single repetition in each slot, with each repetition occupying the same symbols. In some TDD UL/DL configurations, there are a small number of contiguous UL slots in a radio frame. Multiple PUSCH repetitions don't have to be in contiguous slot, but the DL slots are counted as slots for PUSCH repetitions.

Two enhancements of PUSCH repetition Type A were agreed for Rel-17 NR coverage enhancement WI.

### PUSCH Repetition Type A

Opt.1: Increasing the maximum number of repetitions up to a number to be determined during the course of the work.

Opt.2: The number of repetitions counted on the basis of available UL slots.

Regarding Option 2, definition of available slot was discussed in 3GPP. Determination of available slot is still being discussed.

### Agreements:

For defining available slots: a slot is determined as unavailable if at least one of the symbols indicated by TDRA for a PUSCH in the slot overlaps with the symbol not intended for UL transmissions

### FFS Details

TBoMS (Transport Block over Multiple Slots) transmission in NR Rel-17

In NR Rel-15/16, one UL TB is confined to the UL symbols in a slot. To support high data rate, multiple PRBs in a slot can be used for the transmission of a large TB and the multiple PRBs share UE transmission power. Transport block (TB) processing over multiple slots was proposed as a candidate solution of coverage enhancement of PUSCH in NR Rel-17. Multi-slot TB extends the time domain resource for the transmission of a TB across slot border to increase total power for transmission of a TB compared to TB transmission in a single slot, and to reduce CRC overhead in the slots except the last slot of the TB compared to the PUSCH repetition technique in time domain.

### Working Assumption

A transmission occasion for TBoMS (TOT) is constituted of at least one slot or multiple consecutive physical slots for UL transmission

FFS: whether the concept of TOT will be used for designing aspects related to signal generation, e.g., rate-matching, power control, etc.

FFS: whether such concept will be specified or not.

### Agreement:

The structure of TBoMS will be according to only one of these two options (to be down-selected in RAN1 #106-e)

Option 3, if a design based on single RV is adopted.

Option 4, if a design based on different RVs is adopted.

FFS: other details, e.g., rate-matching, TBS determination, collision handling, etc.

The single RV is not constrained to have only the same coded bits in each slot or in each TOT

The concept of TOT as per the corresponding Working assumption is used to define Option 3 and Option 4 and may or may not be used to design other details, e.g., rate-matching, TBS determination, collision handling and so on.

### Agreement:

The following three options for rate-matching for TBoMS are considered for down-selection during RAN1 #106-e, where only one option will be selected:
Option a: Rate-matching is performed per slot;
Option b: Rate matching is performed continuously across all the allocated slot(s) per TOT;
Option c: Rate matching is performed continuously across all the allocated slots/TOTs for TBoMS

Note: “rate-matching is performed per X” means that the time unit for the bit selection and bit interleaving is X.

Note2: the above 3 options imply that the UL resource in the time unit may or may not be consecutive (depending on the given option)

### Agreement:

The following approach is used to calculate N_{Info} for TBoMS:

Approach 2: Based on the number of REs determined in the first L symbols over which the TBoMS transmission is allocated, scaled by κ>1.

FFS: the definition of K.

L is the number of symbols determined using the SLIV of PUSCH indicated via TDRA

FFS: impacts and further details if repetitions of TBoMS is supported.

FFS: whether the symbols over which the TBoMS transmission is allocated are the same or can be different from the symbols over which the TBoMS transmission is performed, and details on how to handle such scenarios.

### Agreement:

Time domain resource determination for TBoMS can be performed only via PUSCH repetition Type A like TDRA.

### FFS: Details

FFS: whether or not optimizations for time domain resource determination are necessary for allocating resource in the S slots (for the unpaired spectrum case)

Different number of consecutive UL slots may be included in one transmission occasion of TBoMS depending the TDD pattern used in a TDD operation. In such cases, same or different TOT size of a TBoMS transmission may be determined, and some rules or explicit signaling may be needed to determine the number of TOTs and the TOT size for the transmission of TBoMS.

Transmission of TBoMS can be based on available slot. If multiple RVs are used across TOTs of a TBoMS, and TOT comprises one or multiple slots, UE needs to determine available TOT. The definition and determination of available TOT need consideration.

Though with multiple slots, the slots of a TBoMS are not repetition of each other. There is no scheme to retransmit part of a TBoMS. Therefore, the legacy UCI multiplexing on PUSCH by rate matching or puncturing needs update for TBoMS.

In NR Rel-15 and Rel-16 one rate matching is performed per CB if CB segmentation happens, otherwise one rate matching is performed per TB. But for TBoMS, each CB/TB may be rate matched multiple times depending on the time unit of rate matching. The rate matching output sequence length needs update. With CB segmentation, it needs to be solved whether the same or different RVs/RV patterns apply to the multiple CBs of a TBoMS.

This invention provides methods on how to:
Determine the TOTs for one TBoMS transmission;
Determine the UCI multiplexing on TBoMS especially when TOT is defined;
Determine the rate matching output sequence length if time unit of rate matching is a slot or a TOT;
Determine the number of slots for the actual transmission of TBoMS;
Determine RV for a rate matching for a CB.

This invention provides methods on how to determine the TOTs for one TBoMS transmission and how the UCI is multiplexed on TBoMS.

Some aspects of embodiments and sub-embodiments for TOT and/or TBoMS size determination can be further described as follows:
1. (Adjust the number of TOTs if TOT size is constant, and the length of at least one TOT if the duration of the TBoMS is fixed) A method in a UE of adjusting the resources occupied by a transport block transmitted over multiple slots, a TBoMS, such that a duration over which rate matching is performed is compatible with a duration over which the TBoMS is transmitted:
a. Receiving an indication of a first number of slots for the transmission of the TBoMS;
b. Determining a plurality of time intervals over which rate matching of the TBoMS is performed, each time interval containing a number of OFDM symbols, and at least one of:
   i. if the plurality of time intervals contain different numbers of OFDM symbols, determining the durations of the time intervals such that the total number of slots occupied by the time intervals is equal to the first number of slots and transmitting the TBoMS in the first number of slots, and
   ii. if the plurality of time intervals each contain a same number of OFDM symbols, determining a second number of slots for the transmission of the TBoMS and transmitting the TBoMS in the second number of slots.
2. (The total number of consecutive slots matches the TBoMS allocation or, alternatively, the number of TOTs is rounded up or down such that the TBoMS transmission contains an integer number of TOTs) The method of 1, further comprising at least one of:
a. When the plurality of time intervals contain different numbers of OFDM symbols, the TBoMS duration is determined according to
   i. identifying a set of slots in which the TBoMS is allocated for transmission;
   ii. determining a plurality of subsets of slots of the set, the subsets of slots containing a single slot or consecutive slots available for uplink transmission and together occupying the first number of slots;
b. When the plurality of time intervals each contain a same number of OFDM symbols,
   i. determining the second number of slots as one of N·┌K/N┐ and N └K/N┘, where K is the first number of slots and N is a number of slots corresponding to the same number of OFDM symbols; and
   ii. determining a number of the plurality of time intervals as one of ┌K/N┐ and └K/N┘.
3. (A TBoMS is segmented into equal size (L symbol) code blocks, and code blocks are segmented into either equal or unequal size TOTs.) The method of 1 or 2 further comprising, when the TBoMS transmission contains a number of code blocks, C, and C>1,
a. segmenting the coded bits of a TBoMS transmission into C equally sized coded bit blocks, each corresponding to L symbols of the TBoMS, and at least one of:
   i. if the plurality of time intervals contain different numbers of OFDM symbols, determining the durations of the time intervals such that the total number of symbols occupied by a subset of the time intervals is equal to L
   ii. if the plurality of time intervals each contain a same number of OFDM symbols,
1. determining the second number of slots as one of N′·C·┌K/(N′−C)┐ and N′·C·max(1, └K/(N′−C)┘), where
   a. K is the first number of slots and N′ is a number of slots corresponding to the same number of OFDM symbols, and
   b. N′·┌K/(N′·C)┐ and N′·max(1,└K/(N′·C)┘) is a number of slots that corresponds to a length of L symbols
4. (Coded bits of the code blocks are split into M equal size rate matching intervals) The method of 3, wherein the coded bit blocks contain Eᵣ coded bits and

$${E}_{r} = {N}_{L} \cdot {Q}_{m} \cdot ⌊ \frac{G}{{N}_{L} \cdot {Q}_{m} \cdot {C}^{′} \cdot M} ⌋ ,$$

where M is a number of the time intervals occupied by a coded bit block, N_{L} is a number of transmission layers, Qₘ is a modulation order, G is a total number of coded bits in the TBoMS, and C′=C.

### TBoMS Based on TOT

For TBoMS, the agreements on single or multiple RVs per TBoMS and time unit of rate matching, which are listed in section 2.1.6 can lead to several combinations. For Option 4 TBoMS with multiple RVs, the possible time units for rate matching are Option a per slot and Option b per TOT. RVs update at the border of slot or TOT. Option a defines time unit of bit selection and bit interleaving as a slot but doesn't restrict how bits are selected across slots. For example, Option a doesn't preclude that UE does continuous bit selection from circular buffer for the UL slots in a TOT. Therefore, TOT Option 4-a (the combination of Option 4 and Option a) and 4-b can have the same encoded bits selected, and the difference lies in whether interleaving is done intra-slot or intra-TOT. The transmission of TBoMS is equivalent to repetitions of TOT. The number of TOTs in a TBoMS equals the number of repetitions of TOT in a TBoMS. An example of option 4-a and 4-b for a TBoMS over four slots in TDD UL/DL configuration of DDSUU is illustrated in FIG. 2a.

The combinations of Option 3 TBoMS with single RV and Option a/b/c can have the continuous bits selected across all slots of the TBoMS, but interleaved with different time units, as illustrated in FIG. 2b.

### Agreement:

The following approach is used to calculate NInfo for TBoMS.

Approach 2: Based on the number of REs determined in the first L symbols over which the TBoMS transmission is allocated, scaled by K≥1.

FFS: the definition of K.

According to the above agreement on calculation of NInfo, TBS of a TBoMS was agreed to be based on the scheduled REs in a slot and scaled by K. For Option 3, TBoMS based on single RV, TBS is scaled by K, which equals the number of slots per TBoMS. For Option 4 TBoMS based on different RVs, if TBS of the TBoMS is based on number of resources in a TOT, namely, K equals the number of slots in a TOT, the TBoMS is repetitions of a TOT. This implies that all TOTs of a TBoMS based on multiple RVs must have the same number of slots.

In this invention, a transmission instance means a time duration with a number of consecutive slots in one TBoMS transmission. One TBoMS transmission may comprise of one or multiple transmission instances.

In this invention, TOT is a transmission occasion with a number of consecutive slots for a TBoMS transmission. A TOT can be a whole transmission instance or only a part of a transmission instance.

Note: slot in TBoMS transmission include at least UL slot. Special slot and flexible slot may or may not be included depending on 3GPP agreement. For simplicity, only UL slot is mentioned in this Disclosure.

### Determination of TOT

When scheduling the transmission of TBoMS, it was agreed in RAN1 #105e that “Number of slots allocated for TBoMS is determined by using a row index of a TDRA list, configured via RRC”. As mentioned above, for TBoMS of multiple RVs, a UE may need to determine the size of a TOT (such as a number of slots in a TOT) for TBS determination. For a TBoMS containing a single RV, if the time unit of rate-matching is a TOT, the UE also needs to know the size of a TOT. For example, in UL-heavy TDD configuration or FDD configuration, the consecutive slots for UL transmission can be divided into multiple smaller TOTs for the ease of interleaving. Therefore, for TBoMS based on single or multiple RVs, UE needs to determine the size of a TOT and the number of TOTs in a TBoMS.

Embodiment 1, for the transmission of TBoMS, the size and number of TOTs for a TBoMS can be determined in one or more of the following methods.
the number of slots per TOT is explicitly configured by the network
the number of TOTs in a TBoMS is explicitly configured by the network
the number of repetitions of a TOT for a TBoMS is explicitly configured by the network
the number of slots for a TOT is implicitly determined as the number of consecutive UL slots for the TBoMS transmission.
In this case, different sizes of TOTs may be determined depending on the actual number of consecutive UL slots in each time instance.
It may be desirable that the UL slots to be used to carry the TBoMS do not vary once the UE has begun transmitting a TBoMS. If the UL slots were to vary, the available resource to transmit the TBoMS varies, and the code rate that the TBoMS is transmitted with will not match what it was scheduled for, thereby degrading performance or losing spectral efficiency. Therefore, in some embodiments, avoiding varying UL slots of a TBoMS is accomplished by determining the UL slots that can potentially carry a TBoMS as the UL slots indicated by semi-static signaling such as tdd-UL-DL-ConfigurationCommon or tdd-UL-DL-ConfigurationDedicated. This semi-static signaling ensures that the UL slots are fixed, since it takes effect before or after a PUSCH transmission, unlike DCI signaling that could happened during the transmission of a TBoMS.
the number of slots for a TOT is determined as the number of consecutive available slots for the transmission of TBoMS.
the number of slots per TOT and/or the number of TOTs per TBoMS and/or the number of repetitions of TOT can be either indicated in a TDRA table with a row index indicated in DCI or higher layer signaling, or configured as separate RRC IE.
The size of a TOT is determined by the minimum number of consecutive UL slots in a TBoMS transmission.
In this method, assuming in a TBoMS transmission, the minimum number of consecutive UL slots is N1, and for the transmission instance with larger number, say N2 (N2>N1), of consecutive UL slots, it can be split into multiple, say ceil(N2/N1), TOTs and the first ceil(N2/N1)−1 TOTs have a size of N1 slots, the last TOT in this transmission occasion has N2−N1*(ceil(N2/N1)−1) slots.
With this method, the size and number of TOTs are simply determined by the minimum number of consecutive UL slots in one TBoMS transmission.
FIG. 2c gives an illustration of the method with N1=2 and N2=3 in a case when 2 transmission instances with 2 consecutive UL slots in the first time instance and 3 consecutive UL slots in the 2nd time instance are used for a TBoMS transmission. And 3 TOTs are determined, the first 2 TOTs have size of 2 UL slots while the last TOT has size of 1 UL slot.
The size of a TOT is determined by the greatest common divisor of the set of numbers of consecutive UL slots in a TBoMS transmission.
In this way, different TOT will have same size.
As an example, when a TBoMS transmission has 2 transmission instances with the first transmission instance having 2 consecutive UL slots and the 2nd transmission instance having 4 consecutive UL slots, then the TOT size is equal to 2 which is the greatest common divisor of 2 and 4. So the first transmission occasion and the second transmission occasion will have 1 and 2 TOTs respectively with same TOT size of 2 UL slots.
The size of a TOT is no more than

$$⌊ \frac{K}{C} ⌋ .$$

K denotes the number of slots for the TBoMS and C denotes the number of CBs for the TBoMS.

For TBoMS with different RVs, the number of TOTs per TBoMS equals the number of repetitions of a TOT per TBoMS. The number of slots per TOT*the number of TOTs in a TBoMS=number of slots for a TBoMS.

Embodiment 2, UE can be explicitly or implicitly indicated or it can be predetermined whether the TOTs used for transmission of a TBoMS have the same or different numbers of slots.

For TBoMS with multiple RVs, all TOTs have the same size. For TBoMS with a single RV, a UE can assume TOTs of different sizes are available for the transmission of a TBoMS. For example, in the TDD configuration of DDDSUDDSUU, the UE transmits in the first TOT, which is a single UL slot, and then in the second TOT, which consists of two UL consecutive slots. Different TOT sizes in a TBoMS will cause higher UE complexity than the same TOT size for a TBoMS. If the number of slots per TOT is indicated, it means each TOT for the TBoMS has the same size.

### TBoMS Based on Available TOT

One enhancement of PUSCH repetition Type A being specified in Rel-17 is the repetition based on available slots. Transmission of TBoMS can also be based on available slot or TOT.

Embodiment 3, The transmission of TBoMS can be based on available TOT.

A sub-embodiment of embodiment 3, an available TOT means all the slots in the TOT in accordance with TOT size are determined as available slots for the transmission of TBoMS.

For example, if a UE is indicated the TOT size of two slots, in DDDSUDDSUU, the first TOT has only one UL slot and is not considered as an available TOT.

Another sub-embodiment of embodiment 3, is where an available slot of the transmission of TBoMS can be determined based on one or more of the following configurations:
cell specific TDD uplink downlink configuration
As an example, tdd-UL-DL-ConfigurationCommon is used to determine which slot is available for the transmission of TBoMS.
Dedicated UE-specific TDD uplink downlink configuration
As an example, tdd-UL-DL-ConfigurationDedicated is used to determine which slot is available for the transmission of TBoMS.
configuration in DCI or higher layer signaling for transmission of TBoMS
e.g. which one or both TDD uplink downlink signalings (i.e. dedicated signaling, tdd-UL-DL-ConfigurationDedicated or common signaling) are to be used for available slot determination can be based on DCI or higher layer signaling scheduling TBoMS
if such configuration in DCI is absent, cell specific and dedicated UE-specific TDD uplink downlink configuration are used if provided.
Higher layer signaling can be used to schedule TBoMS with configured grant.
SSB configuration

Another sub-embodiment of embodiment 3, is where an available slot can be determined according to one or more of below rules. The available slot can be determined as:
a UL slot, or
a flexible slot, with all the allocated symbols in a slot according to the TDRA (time domain resource allocation) for TBoMS as UL symbols, or
a flexible slot, with all the allocated symbols in a slot according to the TDRA (time domain resource allocation) for TBoMS as UL or flexible symbols, or
a special slot, with all the allocated symbols in a slot for according to the TDRA (time domain resource allocation) for TBoMS as UL symbols, or
a special slot, with all the allocated symbols in a slot for according to the TDRA (time domain resource allocation) for TBoMS as UL or flexible symbols

Another sub-embodiment of embodiment 3, if a UE is indicated to transmit TBoMS based on available TOTs, it determines a number of available TOTs with one or more of below methods, where K is a nominal number of slots indicated for a TBoMS.
If the TOTs in a TBoMS can have different sizes, the total number of slots in the determined TOTs for the TBoMS is equal to K.
If TOT size is indicated as N slots, the number of determined TOTs per

$$TBoMS = ⌈ \frac{K}{N} ⌉ or ⌊ \frac{K}{N} ⌋ ,$$

and the total number of slots in the TBoMS is adjusted from K to

$$N \cdot ⌈ \frac{K}{N} ⌉ or N \cdot ⌊ \frac{K}{N} ⌋ .$$

Collision Handling with the Time Unit of TOT

Embodiment 4, if UE determines slots for the transmission of TBoMS and then decides to drop the transmission in one slot, which is called the dropped slot in this Disclosure, one or more of the following methods can be used.
Option 1, UE drops the transmission in the TOT starting from the dropped slot.
Option 2, UE drops the transmission of the TOT, which contains the dropped slot.
Option 3, UE drops the transmission of the TBoMS, starting from a TOT which contains the dropped slot.

Option 1 and 2 are different if the dropped slot is not the first slot in a TOT.

Different from PUSCH repetition, slots of the TBoMS comprising single RV are not repetition of each other. So dropping transmission in one slot is more harmful for TBoMS than PUSCH repetition. In RV0, systematic bits are taken out from the circular buffer ahead of parity bits, and the former is more important for UE decoding. Therefore, if the time unit of interleaving is small, e.g. per slot or TOT, the transmission of TBoMS in the first slot(s) or TOT(s) have more systematic bits than the latter slot or TOT.

Embodiment 5, it is predetermined that UE doesn't expect collision to happen in the first X slots or TOTs of a TBoMS with one or more of the following methods.
X can be RRC/DCI or predetermined.
X equals the minimum number of slots which have the sufficient REs to transmit all or part of the systematic bits.

For example, X is predetermined as one.

### UCI Multiplexing on TBoMS

In Rel-15 and Rel-16, if PUCCH and PUSCH overlap in a slot, the UCI may be multiplexed in PUSCH in the slot. Rel-17 TBoMS has the transmission of a TB over multiple slots. It needs consideration how to deal with PUCCH overlapping with a TBoMS. Document with P number 101202 covered ideas of multiplexing UCI in one or multiple slots, repetition of UCI in multiple slots of TBoMS, postponing and cancellation of transmission. While in this Disclosure, we discuss how multiplexing UCI on PUSCH is done, e.g. by rate matching or puncturing.

In Rel-15/16, UCI multiplexing on PUSCH is done per slot, by puncturing or rate-matching around PUSCH. ACK/NACK>2 bit and other UCI are rate matched, 1-2 bit ACK/NACK punctured. Due to code-block-group-based HARQ feedback, ACK/NACK size can be very large in NR. Puncturing large ACK/NACK into PUSCH leads to severe PUSCH performance degradation. Therefore, reserved resources for puncturing PUSCH are based on 2 ACK/NACK bits.

Rate matching requires the UE to calculate the number of modulated UCI symbols first, map UCI on the agreed RE resources in a slot, and then rate match PUSCH in the remaining resources in the slot. The rate-matching includes bit selection and bit interleaving. The number of selected bits is based on the number of remaining REs in the slot for PUSCH. For TBoMS, the possible time units of rate-matching under discussion are a slot, a TOT, and all slots of a TBoMS. If the time unit of rate-matching is a TOT or all slots of the TBoMS, multiplexing UCI by rate-matching it in any slot of the time unit has an impact on PUSCH transmission in other slots of the time unit. For an example of time unit of rate-matching being two slots, if UCI is to be multiplexed in the second slot, a UE needs to calculate the available REs in the two slots for PUSCH excluding those for UCI and then select PUSCH bits and interleave. The complexity of rate-matching increases for TBoMS with a time unit of rate matching larger than a slot. However puncturing UCI into TBoMS doesn't increase complexity regardless of time unit of rate-matching.

As discussed above, it can be advantageous to carry a single redundancy version, such as RV0, across multiple slots of a TBoMS. Such a mapping can allow a lower code rate and improve performance over where multiple RVs are used. However, because TBoMS occupies multiple slots, when a single slot of an RV is lost, because there is no mechanism defined to retransmit a specific portion of an RV that is lost, all slots of the TBoMS may need to be retransmitted. This means that TBoMS transmissions may need to be more conservatively scheduled than, for example, PUSCH repetition type A, in order to avoid the efficiency loss from losing all TBoMS slots, whereas PUSCH repetition type A could retransmit an RV contained in a slot. Therefore, some embodiments, such as embodiment 6, puncture in a limited number of bits, rather than multiplexing a large number of bits into a TBoMS. In some such embodiments, because CSI often a relatively large payload, CSI is dropped rather than multiplexing the CSI onto a slot of a PUSCH containing TBoMS.

One example of two-bit HARQ-ACK is for the two codewords of DL MIMO of 5-8 layers. In reality, the transmission of HARQ-ACK of more than two bits in a slot is possible, for example, in carrier aggregation, or for multiple sub-slot HARQ in a slot.

Embodiment 6, if PUCCH of HARQ-ACK overlaps with one slot of a TBoMS, one or more of the following methods can be applied.
HARQ-ACK is punctured into TBoMS in the overlapping slot
HARQ-ACK is punctured into TBoMS in the overlapping slot if the number of HARQ-ACK bits is below a pre-determined or configured threshold
HARQ-ACK is punctured into TBoMS in the overlapping slot if there is no UL-SCH in the slot
HARQ-ACK is punctured into TBoMS in the overlapping slot according to the decreasing order of PHY priority index if the number of HARQ-ACK exceeds the threshold of maximum number of HARQ bits to be punctured into PUSCH in a slot

A sub-embodiment of embodiment 6, is where the number of HARQ-ACK bits allowed to be multiplexed in a slot of TBoMS by puncturing is RRC/DCI configured or pre-determined.

Another sub-embodiment of embodiment 6, is where the reserved resources for more-than-2-bit HARQ ACK/NACK are also RRC/DCI configured or pre-determined.

Another sub-embodiment of embodiment 6, is where when PUCCH carrying CSI is scheduled to be transmitted in the same slot as a slot of a TBoMS transmission. In this case, CSI is not multiplexed in to the PUSCH carrying TBoMS in the slot, and the CSI is not transmitted, i.e. ‘dropped’. This would be a rule in the specification.

Embodiment 7, the UCI overlapping with TBoMS is multiplexed on TBoMS in one or more of the following methods:
on the first slot of a first TOT
This might be helpful for early UCI detection if it's transmitted on the first TOT.
on the first slot of a TOT overlapping with the UCI transmission slot scheduled
This might be helpful for early UCI detection if it's transmitted on the first slot of the overlapping TOT and it also makes sure other TOT are not affected by the UCI multiplexing.
on the slot overlapping with the UCI transmission slot scheduled

The UCI mentioned in embodiment 7 can be HARQ-ACK only, CSI only or can be both types of UCI.

### Code Block Segmentation

In Rel-15 and Rel-16, CB segmentation happens when 1) N_{info}>3824 and R≤¼, or 2) the quantized intermediate number of information bits N_{info}>8424 and R>¼. CB segmentation is necessary because LDPC's Base Graph 1 (BG1) and Base Graph 2 (BG2) can process a maximum of 8448 and 3824 information bits respectively. The upper limit of the two LDPC base graphs still holds for TBoMS, and therefore CB segmentation is needed for TBoMS in order to reuse LDPC coding.

In Rel-15 and Rel-16, if the TBS and code rate meet the prerequisites of CB segmentation, multiple CBs are generated, each with the same number of information bits per code block, as described in section 2.1.1 above. Each CB undergoes separate LDPC coding and rate matching before being concatenated, and then RE mapping in a slot. (Scrambling, modulation etc., before RE mapping are not mentioned here for simplicity.) For a TBoMS, each CB is processed independently with LDPC coding, rate matching. Rate matching with CB segmentation is illustrated in FIG. 3.

In NR Rel-15 and Rel-16, one rate matching is performed per CB. If no CB segmentation happens, one rate matching is performed per TB. For Option c, each CB has one rate matching. Each CB's rate matching output sequence length can be determined by the legacy method, then concatenated and continuously mapped to REs in multiple slots. But now with option a and option b for a TBoMS, a CB may undergo multiple times of rate matching depending on the time unit of rate matching. The legacy method of determination of rate matching output sequence length is for a CB and it can't be used directly for multiple times of rate matching for a CB.

Denote K as the number of slots for a TBoMS, and C as the number of CBs for the TBoMS. C=1 if no CB segmentation happens. Also, the time unit of rate matching consists of N slot(s). N=1 if the time unit of rate matching is per slot. N equals the number of slots in a TOT if rate matching is performed per TOT.

A problem for Options a and b is how to do rate matching if mod(K,C)>0 for option a or mod(K, C*TOT size)>0 for option b, where mod(K,C) is modulo division of K by C.

If the rate matched code block does not fit into an integer number of rate matching time units, it is possible to adjust the number of rate matching time units, while keeping the time unit sizes equal. In this way, the total number of slots in a TBoMS may be different from the nominal number of slots in the TBoMS, K, but the rate matched code block will fit into an integer number of rate matching time units. Note that this method exploits the Rel-15/16 property of TBS determination that the TBS is the same for each coded block. Because the TBS is the same, then a single scaling factor can be used that applies to all code blocks that adjusts the number of rate matching time units. Embodiment 8 Options 1, 1a, and 1b capture this approach below.

It is also possible to adjust the size of the rate matching time units such that they are unequally sized in order to fit a rate matched code block into its portion of the resource elements of a TBoMS. One time unit could be rate matched over a portion of a slot or a TOT, while the remaining time units could be rate matched with a second size that is a full slot or TOT. This allows the rate matched code blocks to fit in the number of nominal number of slots allocated for the TBoMS, and corresponds to Embodiment 8, Option 2.

Embodiment 8, the total number of slots for the actual TBoMS transmission, A, can be determined by one or more of the following methods.
Option 1,

$$A = N \cdot C \cdot ⌈ \frac{K}{N \cdot C} ⌉$$

Option 1a

$$A = N \cdot C \cdot max ( 1 , ⌊ \frac{K}{N \cdot C} ⌋ )$$

Option 1b

$$A = N \cdot C \cdot max ( 1 , ⌊ \frac{K}{N \cdot C} ⌋ ) ,$$

if mod(K,C)<C/2; otherwise

$$A = N \cdot C \cdot ⌈ \frac{K}{N \cdot C} ⌉$$

Option 2, A=K

With Options 1, 1a, and 1b, each rate matching is over the same size time unit (that is, over the same number of OFDM symbols) and it may use more slots than configured. Embodiment 9 is about the determination of rate matching output sequence length. Option 2 means the number of slots for the actual TBoMS transmission is the same as its configuration, and the rate matching may not be over the same number of symbols. If K is not divided by C and N, some enhancement is needed, as stated in Embodiment 10.

For example, a TBoMS over five slots is segmented into two CBs. Option 1 is illustrated in FIG. 4a. With option a, when the time unit of rate matching is a slot, each CB is rate matched three times. With option b, when the time unit of rate matching is a two slot long TOT, each CB is rate matched two times. In this example, option a and option b, respectively, use 6 and 8 slots for actual transmission.

Embodiment 9, the rate matching output sequence length for the r-th coded block can be determined by the following method. In the following, the symbol ‘=>’ indicates that the currently specified equation for Eᵣ on the left side of the => is replaced by the new equation for Eᵣ on the right side of the =>.

Denoting by Eᵣ the rate matching output sequence length for the r-th coded block, where the value of Eᵣ is determined as follows:
Set j=0
for r=0 to C−1
   if the r-th coded block is not scheduled for transmission as indicated by CBGTI according to Clause 5.1.7.2 for DL-SCH and 6.1.5.2 for UL-SCH in [6, TS 38.214]

```
  Eᵣ = 0;
else
if j ≤ C'−mod(G/(N_{L} ·Qₘ),C')−1
      ${E}_{r} = {N}_{L} \cdot {Q}_{m} \cdot ⌊ \frac{G}{{N}_{L} \cdot {Q}_{m} \cdot {C}^{′}} ⌋ ; \text{=>} {E}_{r} = {N}_{L} \cdot {Q}_{m} \cdot ⌊ \frac{G}{{N}_{L} \cdot {Q}_{m} \cdot {C}^{′} \cdot M} ⌋$
    else
      ${E}_{r} = {N}_{L} \cdot {Q}_{m} \cdot ⌈ \frac{G}{{N}_{L} \cdot {Q}_{m} \cdot {C}^{′}} ⌉ ; \text{=>} {E}_{r} = {N}_{L} \cdot {Q}_{m} \cdot ⌈ \frac{G}{{N}_{L} \cdot {Q}_{m} \cdot {C}^{′} \cdot M} ⌉$
end if
  j = j+1;
end if
end for
```

where
   N_{L} is the number of transmission layers that the transport block is mapped onto;
   Qₘ is the modulation order;
   G is the total number of coded bits available for transmission of the transport block;
   C′=C if CBGTI is not present in the DCI scheduling the transport block and C′ is the number of scheduled code blocks of the transport block if CBGTI is present in the DCI scheduling the transport block;
   M is the number of times a code block is rate matched.

A sub-embodiment of embodiment 9, M is determined by one or more of the following methods.

$$\begin{matrix}M = ⌈ \frac{K}{N \cdot C} ⌉ \\ M = max ( 1 , ⌊ \frac{K}{N \cdot C} ⌋ )\end{matrix}$$

To make sure the number of slots for the actual transmission of a TBoMS is the same as its configured number of slots, namely option 2 in Embodiment 8, if mod(K, C*N)>0, different numbers of bits are selected for each rate matching.

Embodiment 10, each CB uses the same number of resource elements, which may not be contained in an integer number of slots or TOTs. The CBs together occupy a total of K slots for the TBoMS.

The dividing line between the transmission of two CBs is called a “CB boundary” in this Disclosure.

A sub-embodiment of embodiment 10, the output sequence length of the last rate matching of a CB is determined by the resources between the beginning of the time unit of rate matching and CB boundary. The output sequence length of the first rate matching of a CB other than the first CB of the TBoMS is determined by the resources between the CB boundary and the end of the time unit of rate matching.

As illustrated in FIG. 4b, TBoMS over five slots with two CBs has the CB boundary in the middle of the third slot. For Option a, the last rate matching of CB1 selects coded bits for the first half of the third slot, and the first rate matching of CB2 selects coded bits for the remaining portion of the slot. For option b, a TOT consists of two slots. The first rate matching of CB2 selects coded bits for the latter one and a half slots in the second TOT.

For option 3 TBoMS based on single RVs, if CB segmentation happens, single RV is used for a CB. Whether the multiple CBs use the same or different RVs can be considered. Option 4, TBoMS based on multiple RVs, means RVs cycle across the time unit of rate matching for a CB, if CB segmentation happens. Problems need to be solved, e.g. the same or different RV patterns are used for the multiple CBs, and RV cycles within a CB or across CBs.

Embodiment 11, if CB segmentation applies, RV(s) for each CB can be determined by one or more of the following methods.
Alt 1: one RV is indicated or pre-determined for all CBs.
Alt 2: one RV is indicated or pre-determined for each CB.
Alt 3: one RV pattern is indicated or pre-determined for all CBs.
RVs cycle according to the RV pattern either within a CB, or across CBs.
Alt 4: one RV pattern is indicated or pre-determined for each CB.
Alt 5: one starting RV is indicated or pre-determined for all CBs according to the RV pattern.
Alt 6: one starting RV is indicated or pre-determined for each CB according to the RV pattern.

For example, for option 3, Alt 1 and Alt 2 support all CBs use the same or different RVs respectively. For option 4, RV patterns for different CBs can be the same or different according to Alt 3 and Alt 4.

With Alt 3, one possibility is that multiple RVs cycle across the multiple times of rate matching for a CB. Another one is that multiple RVs cycle across the multiple times of rate matching of all CBs, namely if one RV pattern is configured for the TBoMS, and the starting RV for the first CB is indicated, the starting RV of a subsequent CB follows the last RV of the previous CB according to the RV pattern.

### Generalized Embodiments

This section considers some aspects of TOT and TBoMS size determination, including how to adjust the TOT size or the TBoMS size if the number of TOTs and/or the TOT size are inconsistent with the signaled TBoMS size, addressing issues such as the number of consecutive UL slots and the number or code blocks.

Embodiment 12: In a generalization of embodiments 1 and 2, the number of TOTs is adjusted if the TOT size is constant, while the length of at least one TOT is adjusted if the duration of the TBoMS is fixed. In this embodiment, the time intervals over which rate matching is performed are TOTs. The UE of adjusts the resources occupied by a TBoMS such that a duration over which rate matching is performed is compatible with a duration over which the TBoMS is transmitted. The UE receives an indication of a first number of slots for the transmission of the TBoMS. The UE also determines a plurality of time intervals over which rate matching of the TBoMS is performed, each time interval containing a number of OFDM symbols. The UE also performs at least one of: i) if the plurality of time intervals contain different numbers of OFDM symbols, determining the durations of the time intervals such that the total number of slots occupied by the time intervals is equal to the first number of slots and transmitting the TBoMS in the first number of slots, and ii) if the plurality of time intervals each contain a same number of OFDM symbols, determining a second number of slots for the transmission of the TBoMS and transmitting the TBoMS in the second number of slots.

Embodiment 13: In sub-embodiment of embodiment 12, and generalizing embodiment 3, the total number of consecutive slots matches the TBoMS allocation or, alternatively, the number of TOTs is rounded up or down such that the TBoMS transmission contains an integer number of TOTs. The UE performs the method of embodiment 12, further comprising at least one of a first and a second alternative. In the first alternative, when the plurality of time intervals contain different numbers of OFDM symbols, the TBoMS duration is determined according to identifying a set of slots in which the TBoMS is allocated for transmission, and determining a plurality of subsets of slots of the set, the subsets of slots containing a single slot or consecutive slots available for uplink transmission and together occupying the first number of slots. In the second alternative, when the plurality of time intervals each contain a same number of OFDM symbols, the UE determines the second number of slots as one of N·┌K/N┐ and N·└K/N┘, where K is the first number of slots and N is a number of slots corresponding to the same number of OFDM symbols, and determines a number of the plurality of time intervals as one of ┌K/N┐ and └K/N┘.

Embodiment 14: In a sub-embodiment of embodiment 12 or 13, and generalizing embodiment 8, a TBoMS is segmented into equal size (L symbol) code blocks, and code blocks are segmented into either equal or unequal size rate matching intervals. When the TBoMS transmission contains a number of code blocks, C, and C>1, the UE segments the coded bits of a TBoMS transmission into C equally sized coded bit blocks, each corresponding to L symbols of the TBoMS. The UE performs at least one of a first and a second alternative. In the first alternative, if the plurality of time intervals contain different numbers of OFDM symbols, the UE determines the durations of the time intervals such that the total number of symbols occupied by a subset of the time intervals is equal to L. In the second alternative, if the plurality of time intervals each contain a same number of OFDM symbols, the UE determines the second number of slots as one of N′·C·┌K/(N′·C)┐ and N′·C·max(1, └K/(N′·C)┘), where K is the first number of slots and N′ is a number of slots corresponding to the same number of OFDM symbols, and where N′·┌K/(N′·C)┐ and N′·max(1,└K/(N′·C)┘) is a number of slots that corresponds to a length of L symbols.

Embodiment 15: In a sub-embodiment of embodiment 12 or 13, and generalizing embodiment 9, the UE splits coded bits of the code blocks into M equal size rate matching time intervals. In this sub-embodiment, the coded bit blocks determined by the UE contain Eᵣ coded bits and the UE determines Eᵣ according to

$${E}_{r} = {N}_{L} \cdot {Q}_{m} \cdot ⌊ \frac{G}{{N}_{L} \cdot {Q}_{m} \cdot {C}^{′} \cdot M} ⌋ ,$$

where M is a number of the time intervals occupied by a coded bit block, N_{L} is a number of transmission layers, Qₘ is a modulation order, G is a total number of coded bits in the TBoMS, and C′=C.

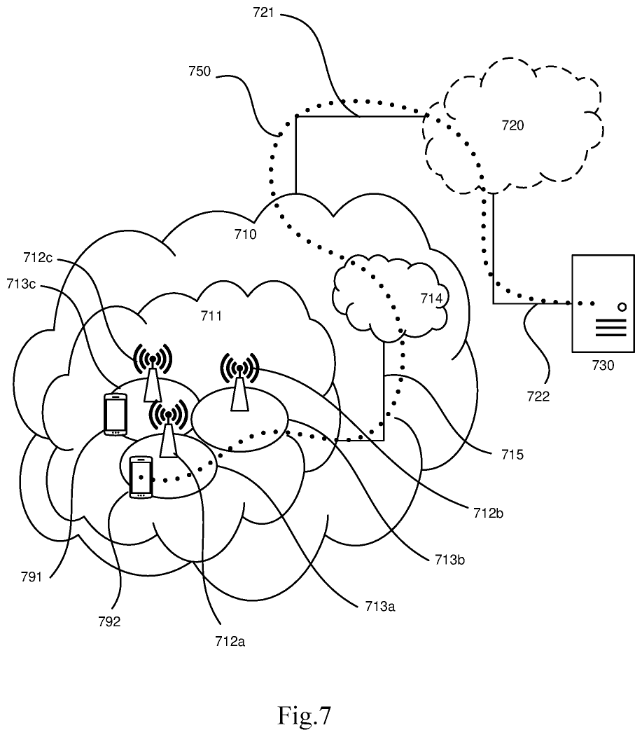

FIG. 7 is a block diagram illustrating a telecommunication network connected via an intermediate network to a host computer in accordance with some embodiments of the present disclosure.

With reference to FIG. 7, in accordance with an embodiment, a communication system includes a telecommunication network 710, such as a 3GPP-type cellular network, which comprises an access network 711, such as a radio access network, and a core network 714. The access network 711 comprises a plurality of base stations 712a, 712b, 712c, such as NBs, eNBs, gNBs or other types of wireless access points, each defining a corresponding coverage area 713a, 713b, 713c. Each base station 712a, 712b, 712c is connectable to the core network 714 over a wired or wireless connection 715. A first UE 791 located in a coverage area 713c is configured to wirelessly connect to, or be paged by, the corresponding base station 712c. A second UE 792 in a coverage area 713a is wirelessly connectable to the corresponding base station 712a. While a plurality of UEs 791, 792 are illustrated in this example, the disclosed embodiments are equally applicable to a situation where a sole UE is in the coverage area or where a sole UE is connecting to the corresponding base station 712.

The telecommunication network 710 is itself connected to a host computer 730, which may be embodied in the hardware and/or software of a standalone server, a cloud-implemented server, a distributed server or as processing resources in a server farm. The host computer 730 may be under the ownership or control of a service provider, or may be operated by the service provider or on behalf of the service provider. Connections 721 and 722 between the telecommunication network 710 and the host computer 730 may extend directly from the core network 714 to the host computer 730 or may go via an optional intermediate network 720. An intermediate network 720 may be one of, or a combination of more than one of, a public, private or hosted network; the intermediate network 720, if any, may be a backbone network or the Internet; in particular, the intermediate network 720 may comprise two or more sub-networks (not shown).

The communication system of FIG. 7 as a whole enables connectivity between the connected UEs 791, 792 and the host computer 730. The connectivity may be described as an over-the-top (OTT) connection 750. The host computer 730 and the connected UEs 791, 792 are configured to communicate data and/or signaling via the OTT connection 750, using the access network 711, the core network 714, any intermediate network 720 and possible further infrastructure (not shown) as intermediaries. The OTT connection 750 may be transparent in the sense that the participating communication devices through which the OTT connection 750 passes are unaware of routing of uplink and downlink communications. For example, the base station 712 may not or need not be informed about the past routing of an incoming downlink communication with data originating from the host computer 730 to be forwarded (e.g., handed over) to a connected UE 791. Similarly, the base station 712 need not be aware of the future routing of an outgoing uplink communication originating from the UE 791 towards the host computer 730.

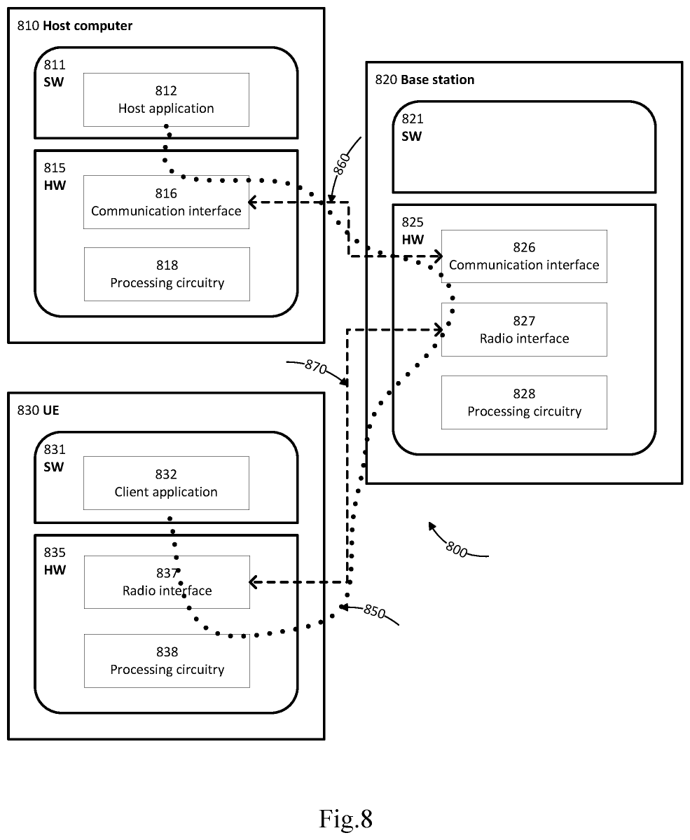

FIG. 8 is a block diagram illustrating a host computer communicating via a base station with a UE over a partially wireless connection in accordance with some embodiments of the present disclosure.

Example implementations, in accordance with an embodiment, of the UE, base station and host computer discussed in the preceding paragraphs will now be described with reference to FIG. 8. In a communication system 800, a host computer 810 comprises hardware 815 including a communication interface 816 configured to set up and maintain a wired or wireless connection with an interface of a different communication device of the communication system 800. The host computer 810 further comprises a processing circuitry 818, which may have storage and/or processing capabilities. In particular, the processing circuitry 818 may comprise one or more programmable processors, application-specific integrated circuits, field programmable gate arrays or combinations of these (not shown) adapted to execute instructions. The host computer 810 further comprises software 811, which is stored in or accessible by the host computer 810 and executable by the processing circuitry 818. The software 811 includes a host application 812. The host application 812 may be operable to provide a service to a remote user, such as UE 830 connecting via an OTT connection 850 terminating at the UE 830 and the host computer 810. In providing the service to the remote user, the host application 812 may provide user data which is transmitted using the OTT connection 850.

The communication system 800 further includes a base station 820 provided in a telecommunication system and comprising hardware 825 enabling it to communicate with the host computer 810 and with the UE 830. The hardware 825 may include a communication interface 826 for setting up and maintaining a wired or wireless connection with an interface of a different communication device of the communication system 800, as well as a radio interface 827 for setting up and maintaining at least a wireless connection 870 with the UE 830 located in a coverage area (not shown in FIG. 8) served by the base station 820. The communication interface 826 may be configured to facilitate a connection 860 to the host computer 810. The connection 860 may be direct or it may pass through a core network (not shown in FIG. 8) of the telecommunication system and/or through one or more intermediate networks outside the telecommunication system. In the embodiment shown, the hardware 825 of the base station 820 further includes a processing circuitry 828, which may comprise one or more programmable processors, application-specific integrated circuits, field programmable gate arrays or combinations of these (not shown) adapted to execute instructions. The base station 820 further has software 821 stored internally or accessible via an external connection.

The communication system 800 further includes the UE 830 already referred to. Its hardware 835 may include a radio interface 837 configured to set up and maintain a wireless connection 870 with a base station serving a coverage area in which the UE 830 is currently located. The hardware 835 of the UE 830 further includes a processing circuitry 838, which may comprise one or more programmable processors, application-specific integrated circuits, field programmable gate arrays or combinations of these (not shown) adapted to execute instructions. The UE 830 further comprises software 831, which is stored in or accessible by the UE 830 and executable by the processing circuitry 838. The software 831 includes a client application 832. The client application 832 may be operable to provide a service to a human or non-human user via the UE 830, with the support of the host computer 810. In the host computer 810, an executing host application 812 may communicate with the executing client application 832 via the OTT connection 850 terminating at the UE 830 and the host computer 810. In providing the service to the user, the client application 832 may receive request data from the host application 812 and provide user data in response to the request data. The OTT connection 850 may transfer both the request data and the user data. The client application 832 may interact with the user to generate the user data that it provides.

It is noted that the host computer 810, the base station 820 and the UE 830 illustrated in FIG. 8 may be similar or identical to the host computer 730, one of base stations 712a, 712b, 712c and one of UEs 791, 792 of FIG. 7, respectively. This is to say, the inner workings of these entities may be as shown in FIG. 8 and independently, the surrounding network topology may be that of FIG. 7.

In FIG. 8, the OTT connection 850 has been drawn abstractly to illustrate the communication between the host computer 810 and the UE 830 via the base station 820, without explicit reference to any intermediary devices and the precise routing of messages via these devices. Network infrastructure may determine the routing, which it may be configured to hide from the UE 830 or from the service provider operating the host computer 810, or both. While the OTT connection 850 is active, the network infrastructure may further take decisions by which it dynamically changes the routing (e.g., on the basis of load balancing consideration or reconfiguration of the network).

Wireless connection 870 between the UE 830 and the base station 820 is in accordance with the teachings of the embodiments described throughout this disclosure. One or more of the various embodiments improve the performance of OTT services provided to the UE 830 using the OTT connection 850, in which the wireless connection 870 forms the last segment. More precisely, the teachings of these embodiments may improve the latency, and thereby provide benefits such as lower complexity, reduced time required to access a cell, better responsiveness, etc.

A measurement procedure may be provided for the purpose of monitoring data rate, latency and other factors on which the one or more embodiments improve. There may further be an optional network functionality for reconfiguring the OTT connection 850 between the host computer 810 and the UE 830, in response to variations in the measurement results. The measurement procedure and/or the network functionality for reconfiguring the OTT connection 850 may be implemented in software 811 and hardware 815 of the host computer 810 or in software 831 and hardware 835 of the UE 830, or both. In embodiments, sensors (not shown) may be deployed in or in association with communication devices through which the OTT connection 850 passes; the sensors may participate in the measurement procedure by supplying values of the monitored quantities exemplified above, or supplying values of other physical quantities from which the software 811, 831 may compute or estimate the monitored quantities. The reconfiguring of the OTT connection 850 may include message format, retransmission settings, preferred routing etc.; the reconfiguring need not affect the base station 820, and it may be unknown or imperceptible to the base station 820. Such procedures and functionalities may be known and practiced in the art. In certain embodiments, measurements may involve proprietary UE signaling facilitating the host computer 810's measurements of throughput, propagation times, latency and the like. The measurements may be implemented in that the software 811 and 831 causes messages to be transmitted, in particular empty or ‘dummy’ messages, using the OTT connection 850 while it monitors propagation times, errors etc.

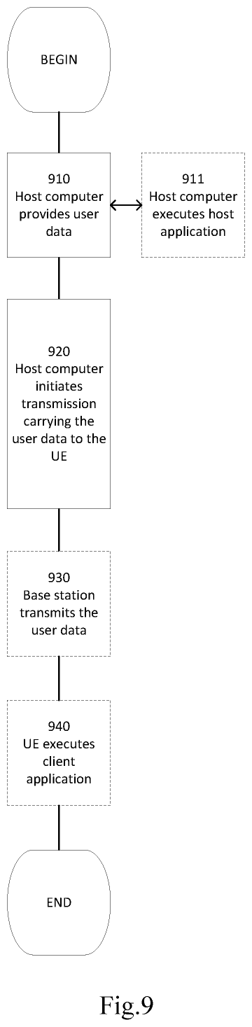

FIG. 9 is a flowchart illustrating a method implemented in a communication system, in accordance with an embodiment. The communication system includes a host computer, a base station and a UE which may be those described with reference to FIG. 7 and FIG. 8. For simplicity of the present disclosure, only drawing references to FIG. 9 will be included in this section. In step 910, the host computer provides user data. In substep 911 (which may be optional) of step 910, the host computer provides the user data by executing a host application. In step 920, the host computer initiates a transmission carrying the user data to the UE. In step 930 (which may be optional), the base station transmits to the UE the user data which was carried in the transmission that the host computer initiated, in accordance with the teachings of the embodiments described throughout this disclosure. In step 940 (which may also be optional), the UE executes a client application associated with the host application executed by the host computer.

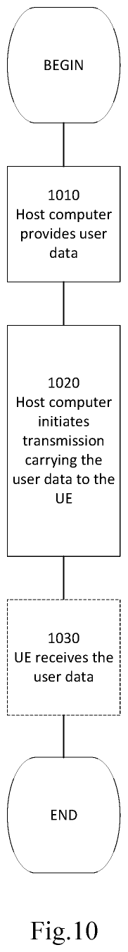

FIG. 10 is a flowchart illustrating a method implemented in a communication system, in accordance with an embodiment. The communication system includes a host computer, a base station and a UE which may be those described with reference to FIG. 7 and FIG. 8. For simplicity of the present disclosure, only drawing references to FIG. 10 will be included in this section. In step 1010 of the method, the host computer provides user data. In an optional substep (not shown) the host computer provides the user data by executing a host application. In step 1020, the host computer initiates a transmission carrying the user data to the UE. The transmission may pass via the base station, in accordance with the teachings of the embodiments described throughout this disclosure. In step 1030 (which may be optional), the UE receives the user data carried in the transmission.

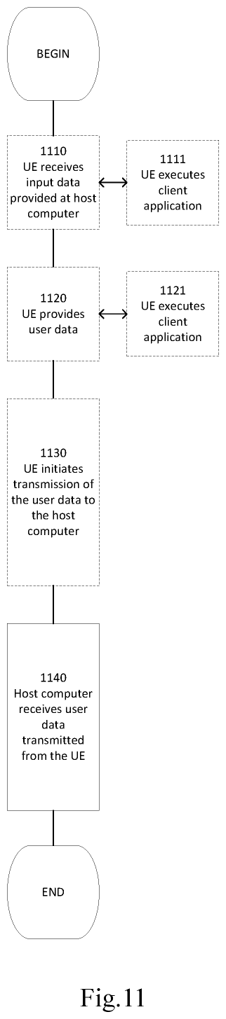

FIG. 11 is a flowchart illustrating a method implemented in a communication system, in accordance with an embodiment. The communication system includes a host computer, a base station and a UE which may be those described with reference to FIG. 7 and FIG. 8. For simplicity of the present disclosure, only drawing references to FIG. 11 will be included in this section. In step 1110 (which may be optional), the UE receives input data provided by the host computer. Additionally or alternatively, in step 1120, the UE provides user data. In substep 1121 (which may be optional) of step 1120, the UE provides the user data by executing a client application. In substep 1111 (which may be optional) of step 1110, the UE executes a client application which provides the user data in reaction to the received input data provided by the host computer. In providing the user data, the executed client application may further consider user input received from the user. Regardless of the specific manner in which the user data was provided, the UE initiates, in substep 1130 (which may be optional), transmission of the user data to the host computer. In step 1140 of the method, the host computer receives the user data transmitted from the UE, in accordance with the teachings of the embodiments described throughout this disclosure.

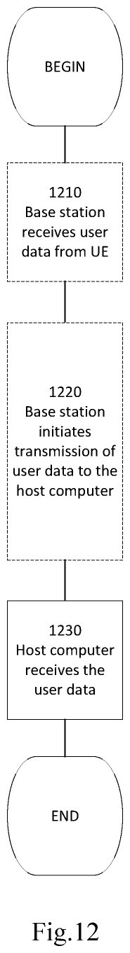

FIG. 12 is a flowchart illustrating a method implemented in a communication system, in accordance with an embodiment. The communication system includes a host computer, a base station and a UE which may be those described with reference to FIG. 7 and FIG. 8. For simplicity of the present disclosure, only drawing references to FIG. 12 will be included in this section. In step 1210 (which may be optional), in accordance with the teachings of the embodiments described throughout this disclosure, the base station receives user data from the UE. In step 1220 (which may be optional), the base station initiates transmission of the received user data to the host computer. In step 1230 (which may be optional), the host computer receives the user data carried in the transmission initiated by the base station.

According to some exemplary embodiments, there is provided a method implemented in a communication system which may include a host computer, a base station and a UE. The method may comprise providing user data at the host computer. Optionally, the method may comprise, at the host computer, initiating a transmission carrying the user data to the UE via a cellular network comprising the base station which may perform any step of the exemplary method 500 as describe with respect to FIG. 5.

According to some exemplary embodiments, there is provided a communication system including a host computer. The host computer may comprise processing circuitry configured to provide user data, and a communication interface configured to forward the user data to a cellular network for transmission to a UE. The cellular network may comprise a base station having a radio interface and processing circuitry. The base station's processing circuitry may be configured to perform any step of the exemplary method 500 as described with respect to FIG. 5.

According to some exemplary embodiments, there is provided a method implemented in a communication system which may include a host computer, a base station and a UE. The method may comprise providing user data at the host computer. Optionally, the method may comprise, at the host computer, initiating a transmission carrying the user data to the UE via a cellular network comprising the base station. The UE may perform any step of the exemplary method 100 as described with respect to FIG. 1.

According to some exemplary embodiments, there is provided a communication system including a host computer. The host computer may comprise processing circuitry configured to provide user data, and a communication interface configured to forward user data to a cellular network for transmission to a UE. The UE may comprise a radio interface and processing circuitry. The UE's processing circuitry may be configured to perform any step of the exemplary method 100 as described with respect to FIG. 1.

According to some exemplary embodiments, there is provided a method implemented in a communication system which may include a host computer, a base station and a UE. The method may comprise, at the host computer, receiving user data transmitted to the base station from the UE which may perform any step of the exemplary method 100 as described with respect to FIG. 1.

According to some exemplary embodiments, there is provided a communication system including a host computer. The host computer may comprise a communication interface configured to receive user data originating from a transmission from a UE to a base station. The UE may comprise a radio interface and processing circuitry. The UE's processing circuitry may be configured to perform any step of the exemplary method 100 as described with respect to FIG. 1.

According to some exemplary embodiments, there is provided a method implemented in a communication system which may include a host computer, a base station and a UE. The method may comprise, at the host computer, receiving, from the base station, user data originating from a transmission which the base station has received from the UE. The base station may perform any step of the exemplary method 500 as described with respect to FIG. 5.

According to some exemplary embodiments, there is provided a communication system which may include a host computer. The host computer may comprise a communication interface configured to receive user data originating from a transmission from a UE to a base station. The base station may comprise a radio interface and processing circuitry. The base station's processing circuitry may be configured to perform any step of the exemplary method 500 as described with respect to FIG. 5.

In general, the various exemplary embodiments may be implemented in hardware or special purpose chips, circuits, software, logic or any combination thereof. For example, some aspects may be implemented in hardware, while other aspects may be implemented in firmware or software which may be executed by a controller, microprocessor or other computing device, although the disclosure is not limited thereto. While various aspects of the exemplary embodiments of this disclosure may be illustrated and described as block diagrams, flow charts, or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

As such, it should be appreciated that at least some aspects of the exemplary embodiments of the disclosure may be practiced in various components such as integrated circuit chips and modules. It should thus be appreciated that the exemplary embodiments of this disclosure may be realized in an apparatus that is embodied as an integrated circuit, where the integrated circuit may comprise circuitry (as well as possibly firmware) for embodying at least one or more of a data processor, a digital signal processor, baseband circuitry and radio frequency circuitry that are configurable so as to operate in accordance with the exemplary embodiments of this disclosure.

It should be appreciated that at least some aspects of the exemplary embodiments of the disclosure may be embodied in computer-executable instructions, such as in one or more program modules, executed by one or more computers or other devices. Generally, program modules include routines, programs, objects, components, data structures, etc. that perform particular tasks or implement particular abstract data types when executed by a processor in a computer or other device. The computer executable instructions may be stored on a computer readable medium such as a hard disk, optical disk, removable storage media, solid state memory, random access memory (RAM), etc. As will be appreciated by one of skill in the art, the function of the program modules may be combined or distributed as desired in various embodiments. In addition, the function may be embodied in whole or partly in firmware or hardware equivalents such as integrated circuits, field programmable gate arrays (FPGA), and the like.

The present disclosure includes any novel feature or combination of features disclosed herein either explicitly or any generalization thereof. Various modifications and adaptations to the foregoing exemplary embodiments of this disclosure may become apparent to those skilled in the relevant arts in view of the foregoing description, when read in conjunction with the accompanying drawings. However, any and all modifications will still fall within the scope of the non-limiting and exemplary embodiments of this disclosure.

1. A method performed by a terminal device, comprising:
encoding with low density parity check, LDPC, base graph on each code block, CB, of a Transport Block over Multiple Slots, TBoMS, wherein the TBoMS comprises multiple slots; and
performing rate matching on the LDPC code for each of the multiple slots of the TBoMS, wherein a time unit of the rate matching is per slot in the TBoMS, and wherein the TBoMS comprises one or more CBs.

2. The method according to claim 1, wherein a rate matching output sequence length Eᵣ for an r-th CB is determined by:
$${E}_{r} = {N}_{L} \cdot {Q}_{m} \cdot ⌊ \frac{G}{{N}_{L} \cdot {Q}_{m} \cdot C ′ \cdot M} ⌋ ,$$
if j≤C′−mod(G/(N_{L}·Qₘ),C′)−1; otherwise
$${E}_{r} = {N}_{L} \cdot {Q}_{m} \cdot ⌈ \frac{G}{{N}_{L} \cdot {Q}_{m} \cdot C ′ \cdot M} ⌉ ;$$
where N_{L} is a number of transmission layers that the transport block is mapped onto; Qₘ is a modulation order; G is a total number of coded bits available for transmitting the transport block; C′=C if CBGTI is not present in the DCI scheduling the transport block, C is a number of CBs for a TBoMS transmission, otherwise C′ is a number of scheduled CBs of the transport block; and M is a number of times that a CB is rate matched.

3. The method according to claim 1, further comprising:
receiving a first indication indicating a first number of slots for a TBoMS transmission; and
determining a set of slots to be used for the TBoMS transmission based on the first indication and obtained TDD or FDD configuration information.

4. The method according to claim 1, wherein the TBoMS comprises one CB.

5. The method according to claim 1, wherein one or more of the followings applies:
a same redundancy version, RV, is indicated or pre-determined for all CBs;
a respective RV is indicated or pre-determined for each CB;
a same RV pattern is indicated or pre-determined for all CBs, wherein an RV cycle according to the RV pattern is performed within a CB, or across CBs;
a respective RV pattern is indicated or pre-determined for each CB;
a same starting RV is indicated or pre-determined for all CBs according to the RV pattern; or
a respective starting RV is indicated or pre-determined for each CB according to the RV pattern.

6. The method according to claim 1, further comprising:
performing one or more of the followings, in response to a Physical Uplink Control Channel, PUCCH, of Hybrid Automatic Repeat Request, HARQ-acknowledge, ACK, overlaps with a slot of the TBoMS transmission:
puncturing the HARQ-ACK into the TBoMS transmission in the overlapping slot;
puncturing the HARQ-ACK into the TBoMS transmission in the overlapping slot in response to a number of HARQ-ACK bits being lower than a pre-determined or configured threshold;
puncturing the HARQ-ACK into the TBoMS transmission in the overlapping slot in response to no uplink shared channel, UL-SCH, in the overlapping slot; or
puncturing the HARQ-ACK into the TBoMS transmission in the overlapping slot according to a decreasing order of PHY priority indexes in response to the number of HARQ-ACK bits exceeding a maximum number of HARQ bits to be punctured into a Physical Uplink Shared Channel, PUSCH, in one slot.

7. A method performed by a network node, comprising:
receiving a Transport Block over Multiple Slots, TBoMS, wherein the TBoMS comprises multiple slots and comprises one or more code blocks, CBs;
wherein each CB of the TBoMS was encoded with low density parity check, LDPC, base graph, and the LDPC code was rate-matched for each of the multiple slots of the TBoMS.

8. The method according to claim 7, wherein a rate matching output sequence length Eᵣ for an r-th CB is determined by:
$${E}_{r} = {N}_{L} \cdot {Q}_{m} \cdot ⌊ \frac{G}{{N}_{L} \cdot {Q}_{m} \cdot C ′ \cdot M} ⌋ ,$$
if j≤C′−mod (G/(N_{L}·Qₘ),C′)−1; otherwise
$${E}_{r} = {N}_{L} \cdot {Q}_{m} \cdot ⌈ \frac{G}{{N}_{L} \cdot {Q}_{m} \cdot C ′ \cdot M} ⌉ ;$$
where N_{L} is a number of transmission layers that the transport block is mapped onto; Qₘ is a modulation order; G is a total number of coded bits available for transmitting the transport block; C′=C if CBGTI is not present in the DCI scheduling the transport block, C is a number of CBs for a TBoMS transmission, otherwise C′ is a number of scheduled CBs of the transport block; and M is a number of times that a CB is rate matched.

9. The method according to claim 7, further comprising:
transmitting a first indication indicating a first number of slots for a TBoMS transmission.

10. The method according to claim 7, wherein the TBoMS comprises one CB.

11. A terminal device, comprising:
one or more processors; and
one or more memories comprising computer program codes,
the one or more memories and the computer program codes configured to, with the one or more processors, cause the terminal device at least to:
encode with low density parity check, LDPC, base graph on each code block, CB, of a Transport Block over Multiple Slots, TBoMS, wherein the TBoMS comprises multiple slots; and
perform rate matching on the LDPC code for each of the multiple slots of the TBoMS, wherein a time unit of the rate matching is per slot in the TBoMS, and wherein the TBoMS comprises one or more CBs.

12. The terminal device according to claim 11, wherein a rate matching output sequence length Eᵣ for an r-th CB is determined by:
$${E}_{r} = {N}_{L} \cdot {Q}_{m} \cdot ⌊ \frac{G}{{N}_{L} \cdot {Q}_{m} \cdot C ′ \cdot M} ⌋ ,$$
if j≤C′−mod(G/(N_{L}·Qₘ),C′)−1; otherwise
$${E}_{r} = {N}_{L} \cdot {Q}_{m} \cdot ⌈ \frac{G}{{N}_{L} \cdot {Q}_{m} \cdot C ′ \cdot M} ⌉ ;$$
where N_{L} is a number of transmission layers that the transport block is mapped onto; Qₘ is a modulation order; G is a total number of coded bits available for transmitting the transport block; C′=C if CBGTI is not present in the DCI scheduling the transport block, C is a number of CBs for a TBoMS transmission, otherwise C′ is a number of scheduled CBs of the transport block; and M is a number of times that a CB is rate matched.

13-16. (canceled)

17. The terminal device according to claim 11, the one or more memories and the computer program codes configured to, with the one or more processors, cause the terminal device to:
receive a first indication indicating a first number of slots for a TBoMS transmission; and
determine a set of slots to be used for the TBoMS transmission based on the first indication and obtained TDD or FDD configuration information.

18. The terminal device according to claim 11, wherein the TBoMS comprises one CB.

19. The terminal device according to claim 11, wherein one or more of the followings applies:
a same redundancy version, RV, is indicated or pre-determined for all CBs;
a respective RV is indicated or pre-determined for each CB;
a same RV pattern is indicated or pre-determined for all CBs, wherein an RV cycle according to the RV pattern is performed within a CB, or across CBs;
a respective RV pattern is indicated or pre-determined for each CB;
a same starting RV is indicated or pre-determined for all CBs according to the RV pattern; or
a respective starting RV is indicated or pre-determined for each CB according to the RV pattern.

20. The terminal device according to claim 11, the one or more memories and the computer program codes configured to, with the one or more processors, cause the terminal device to:
perform one or more of the followings, in response to a Physical Uplink Control Channel, PUCCH, of Hybrid Automatic Repeat Request, HARQ-acknowledge, ACK, overlaps with a slot of the TBoMS transmission:
puncture the HARQ-ACK into the TBoMS transmission in the overlapping slot;
puncture the HARQ-ACK into the TBoMS transmission in the overlapping slot in response to a number of HARQ-ACK bits being lower than a pre-determined or configured threshold;
puncture the HARQ-ACK into the TBoMS transmission in the overlapping slot in response to no uplink shared channel, UL-SCH, in the overlapping slot; or
puncture the HARQ-ACK into the TBoMS transmission in the overlapping slot according to a decreasing order of PHY priority indexes in response to the number of HARQ-ACK bits exceeding a maximum number of HARQ bits to be punctured into a Physical Uplink Shared Channel, PUSCH, in one slot.
